(19) United States
(12) Patent Application Publication
(10) Pub. No.: US 2026/0052713 A1
(43) Pub. Date: Feb. 19, 2026

(54) SEMICONDUCTOR DEVICE AND METHOD FOR MANUFACTURING SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 19/369,283

(22) Filed: Oct. 26, 2025

Related U.S. Application Data
(63) Continuation of application No. PCT/JP2024/040158, filed on Nov. 12, 2024.

(30) Foreign Application Priority Data
Nov. 16, 2023 (JP) 2023-195145

(51) Int. Cl. H10D 8/00; H10D 8/01; H10D 12/00; H10D 12/01; H10D 62/10; H10D 62/60; H10D 84/00

(52) U.S. Cl. CPC H10D 8/422; H10D 8/045; H10D 12/038; H10D 12/481; H10D 62/126; H10D 62/60; H10D 84/143; H10D 84/161

(57) ABSTRACT

Provided is a semiconductor device comprising a semiconductor substrate which has an upper surface and a lower surface, and which is provided with a diode portion, wherein the diode portion includes a first cathode region of a first conductivity type, and a second cathode region of a second conductivity type, and the first cathode region and the second cathode region are provided alternately in a first direction, and a repetition pitch of the first cathode region and the second cathode region in the first direction is 40 μm or more and 200 μm or less, and an area ratio of the second cathode region relative to a sum of areas of the first cathode region and the second cathode region is 0.1 or more and 0.8 or less.

The contents of the following patent application(s) are incorporated herein by reference:
NO. 2023-195145 filed in JP on Nov. 16, 2023
NO. PCT/JP2024/040158 filed in WO on Nov. 12, 2024.

### BACKGROUND

### 1. Technical Field

The present invention relates to a semiconductor device and a method for manufacturing the semiconductor device.

### 2. Related Art

Conventionally, structures in which N type and P type regions are mixed have been known as cathode regions of diodes (for example, see Patent Document 1 and 2).
Patent Document 1: Japanese Patent Application Publication No. 2019-091857
Patent Document 2: Japanese Patent Application Publication No. 2022-015861

### BRIEF DESCRIPTION OF THE DRAWINGS

FIG. 1 is a top plan view illustrating an example of a semiconductor device 100 according to one embodiment of the present invention.

FIG. 2 is an enlarged view of a region D in FIG. 1.

FIG. 3 shows an example of a cross-section e-e in FIG. 2.

FIG. 4A shows an exemplary arrangement of a first cathode region 81 and a second cathode region 82 on a lower surface 23 of a semiconductor substrate 10.

FIG. 4B shows another exemplary arrangement of the first cathode region 81 and the second cathode region 82 in one cathode region 83.

FIG. 4C shows another exemplary arrangement of the first cathode region 81 and the second cathode region 82 in one cathode region 83.

FIG. 5A shows another exemplary arrangement of the first cathode region 81 and the second cathode region 82 in one diode portion 80.

FIG. 5B shows another exemplary arrangement of the first cathode region 81 and the second cathode region 82 in one cathode region 83.

FIG. 5C shows another exemplary arrangement of the first cathode region 81 and the second cathode region 82 in one cathode region 83.

FIG. 6A shows another exemplary arrangement of the first cathode region 81 and the second cathode region 82 in one diode portion 80.

FIG. 6B shows another exemplary arrangement of the first cathode region 81 and the second cathode region 82 in one cathode region 83.

FIG. 6C shows another exemplary arrangement of the first cathode region 81 and the second cathode region 82 in one cathode region 83.

FIG. 7 shows a relationship between an area ratio R and a forward voltage in the diode portion 80.

FIG. 8 shows a relationship between the forward voltage and a reverse recovery loss relative to the area ratio R.

FIG. 9 shows a relationship between the forward voltage and the reverse recovery loss relative to a length Y2 of the second cathode region 82 in the first direction.

FIG. 10 shows a relationship between a magnitude of forward voltage variation due to patterning variation in the manufacturing process and the area ratio R.

FIG. 11 shows a relationship between the magnitude of forward voltage variation due to patterning variation in the manufacturing process and the length Y2 in the second cathode region 82.

FIG. 12 shows a relationship between the magnitude of forward voltage variation and the area ratio R when the patterning variation is assumed to be ±0.2 μm.

FIG. 13 shows a relationship between the magnitude of forward voltage variation and the length Y2 of the second cathode region 82 when the patterning variation is assumed to be ±0.2 μm.

FIG. 14 shows another exemplary relationship between the area ratio R and the forward voltage in the diode portion 80.

FIG. 15 shows a comparative example of an anode voltage-anode current characteristic in the diode portion 80.

FIG. 16 shows another exemplary anode voltage-anode current characteristic in the diode portion 80.

FIG. 17 shows a relationship between the length Y2 of the second cathode region 82 and the forward voltage.

FIG. 18 shows the relationship of the forward voltage-reverse recovery loss of the diode portion 80.

FIG. 19 illustrates a method for manufacturing the semiconductor device 100.

FIG. 20 illustrates an example of a designing step S1002.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in implementation of a semiconductor device.

In the present specification, technical matters may be described by using orthogonal coordinate axes of an X-axis, a Y-axis, and a Z-axis. The orthogonal coordinate axes merely specify relative positions of components, and do not limit a particular direction. For example, the Z-axis is not limited to indicate a height direction with respect to the ground. It is to be noted that a +Z-axis direction and a-Z-axis direction are directions opposite to each other. When the Z-axis direction is described without describing a sign, it means that the direction is parallel to the +Z-axis and the −Z-axis.

In the present specification, orthogonal axes parallel to the upper surface and the lower surface of the semiconductor substrate are referred to as the X-axis and the Y-axis. In addition, an axis perpendicular to the upper surface and the lower surface of the semiconductor substrate is referred to as the Z-axis. In the present specification, the direction of the Z-axis may be referred to as the depth direction. In addition, in the present specification, a direction parallel to the upper surface and the lower surface of the semiconductor substrate may be referred to as a horizontal direction, including an X-axis direction and a Y-axis direction.

region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is Np and the acceptor concentration is NA, the net doping concentration at any position is given as ND-NA. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies the electrons. The hydrogen donor may be a donor obtained by the combination of at least a vacancy (V) and hydrogen (H). Alternatively, interstitial Si—H in which interstitial silicon (Si-i) in a silicon semiconductor is attached to hydrogen, and CiOi-H in which interstitial carbon (Ci) is attached to interstitial oxygen (Oi) and hydrogen also function as a donor which supplies electrons. In the present specification, the VOH defect, the CiOi-H, or the interstitial Si—H may be referred to as the hydrogen donor.

In the semiconductor substrate in the present specification, bulk donors of the N type are distributed throughout. The bulk donor is a dopant donor substantially uniformly contained in an ingot during the manufacture of the ingot from which the semiconductor substrate is made. The bulk donor in the present example is an element other than hydrogen. The bulk donor dopant is, for example, phosphorous, antimony, arsenic, selenium, or sulfur, but the invention is not limited to these. The bulk donor in the present example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in the present example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. In addition, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate is preferably 1×10¹¹/cm³ or more. The bulk donor concentration (DO) of the non-doped substrate is preferably 5×10¹²/cm³ or less. Each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P-type or an N-type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV profiling).

In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. The semiconductor substrate may be silicon, silicon carbide, gallium nitride, diamond, or gallium oxide.

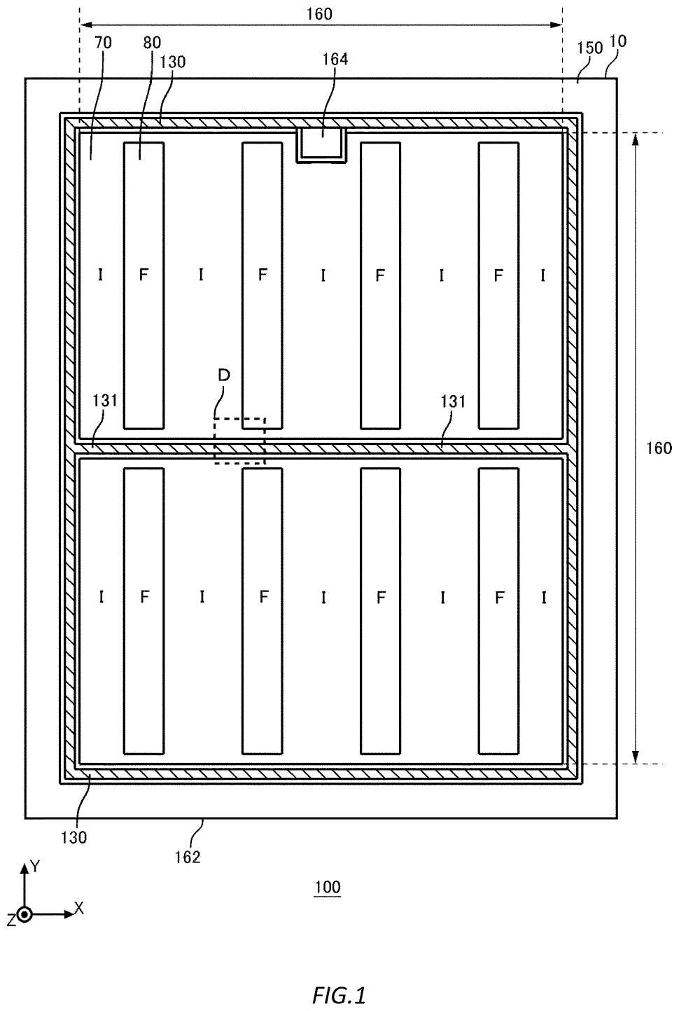

FIG. 1 is a top plan view illustrating an example of a semiconductor device 100 according to one embodiment of the present invention. FIG. 1 illustrates a position at which each member is projected on an upper surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in the present example has two sets of end sides 162 opposite to each other in the top view. In FIG. 1, the X-axis and the Y-axis are parallel to any of the end sides 162. In addition, the Z-axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but is omitted in FIG. 1. The active portion 160 may refer to a region which overlaps with the emitter electrode in the top view. In addition, a region sandwiched between active portions 160 in the top view may also be included in the active portion 160.

A diode portion 80 which includes a diode element such as a freewheeling diode (FWD) is provided in the active portion 160. A transistor portion 70 which includes a transistor device such as an IGBT (Insulated Gate Bipolar Transistor) may further be provided in the active portion 160. In the example shown in FIG. 1, the transistor portions 70 and the diode portions 80 are alternately arranged along a predetermined array direction (the X-axis direction in this example) at the upper surface of the semiconductor substrate 10. The semiconductor device 100 in the present example is a reverse conduction type IGBT (RC-IGBT). The transistor portion 70 and the diode portion 80 are connected in anti-parallel to each other. That is, an emitter of a transistor portion 70 and an anode of a diode portion 80 are electrically connected, and a collector of the transistor portion 70 and a cathode of the diode portion 80 are electrically connected.

In FIG. 1, a region where the transistor portion 70 is arranged is indicated by a symbol “I”, and a region where the diode portion 80 is arranged is indicated by a symbol “F”. In the present specification, a direction perpendicular to the array direction in a top view may be referred to as an extending direction (the Y-axis direction in FIG. 1). The transistor portion 70 and the diode portion 80 may each have a longitudinal length in an extension direction. That is, a length of the transistor portion 70 in the Y-axis direction is larger than its width in the X-axis direction. Similarly, a length of the diode portion 80 in the Y-axis direction is larger than its width in the X-axis direction. The extending directions of the transistor portion 70 and the diode portion 80, and a longitudinal direction of each trench portion described below may be the same.

The diode portion 80 has a first cathode region of N+ type and a second cathode region of P+ type in a region that is in contact with the lower surface of the semiconductor substrate 10. In the present specification, a repetition structure that includes the first cathode region and the second cathode region is periodically arranged in a predetermined direction on the lower surface of the semiconductor substrate 10. A region in which the first cathode region or the second cathode region is arranged is referred to as the diode portion 80. On the lower surface of the semiconductor substrate 10, a P+ type of collector region may be provided in a region other than the diode portion 80.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged at the upper surface side of the semiconductor substrate 10.

The semiconductor device 100 may include one or more pads above the semiconductor substrate 10. The semiconductor device 100 in the present example has a gate pad 164. The semiconductor device 100 may have a pad such as an anode pad, a cathode pad, and a current detection pad. Each pad is arranged in a vicinity of the end side 162. The vicinity of the end side 162 refers to a region between the end side 162 and the emitter electrode in the top view. In implementation of the semiconductor device 100, each pad may be connected to an external circuit via wiring such as a wire.

A gate potential is applied to the gate pad 164. The gate pad 164 is electrically connected to a conductive portion of a gate trench portion of the active portion 160. The semiconductor device 100 includes the gate runner that connects the gate pad 164 to the gate trench portion. In FIG. 1, the gate runner is hatched with diagonal lines.

The gate runner in the present example has an outer circumferential gate runner 130 and an active-side gate runner 131. The outer circumferential gate runner 130 is arranged between the active portion 160 and the end side 162 of the semiconductor substrate 10 in the top view. The outer circumferential gate runner 130 in the present example encloses the active portion 160 in the top view. A region enclosed by the outer circumferential gate runner 130 in the top view may be set as the active portion 160. In addition, a well region is formed below the gate runner. The well region is a P type region having a higher concentration than that of the base region described below, and is formed from the upper surface of the semiconductor substrate 10 to a position deeper than that of the base region. A region enclosed by the well region in the top view may be set as the active portion 160.

The outer circumferential gate runner 130 is connected to the gate pad 164. The outer circumferential gate runner 130 is arranged above the semiconductor substrate 10. The outer circumferential gate runner 130 may be a metal wiring containing aluminum or the like.

The active-side gate runner 131 is provided in the active portion 160. Providing the active-side gate runner 131 in the active portion 160 can reduce a variation in a wiring length from the gate pad 164 for each region of the semiconductor substrate 10.

The outer circumferential gate runner 130 and the active-side gate runner 131 are connected to the gate trench portion of the active portion 160. The outer circumferential gate runner 130 and the active-side gate runner 131 are arranged above the semiconductor substrate 10. The outer circumferential gate runner 130 and the active-side gate runner 131 may be a wiring formed of a semiconductor such as polysilicon doped with an impurity.

The active-side gate runner 131 may be connected to the outer circumferential gate runner 130. The active-side gate runner 131 in the present example is provided to extend in the X-axis direction so as to cross the active portion 160 substantially at the center of the Y-axis direction from one outer circumferential gate runner 130 to another outer circumferential gate runner 130 which sandwich the active portion 160. When the active portion 160 is divided by the active-side gate runner 131, the transistor portions 70 and the diode portions 80 may be alternately arranged in the X-axis direction in each divided region.

The semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of the present example includes an edge termination structure portion 150 between the active portion 160 and the end side 162 in top view. The edge termination structure portion 150 of the present example is arranged between the outer circumferential gate runner 130 and the end side 162. The edge termination structure portion 150 relaxes an electric field strength at an upper surface side of the semiconductor substrate 10. The edge termination structure portion 150 may include at least one of a guard ring, a field plate, or a RESURF which is annularly provided to enclose the active portion 160.

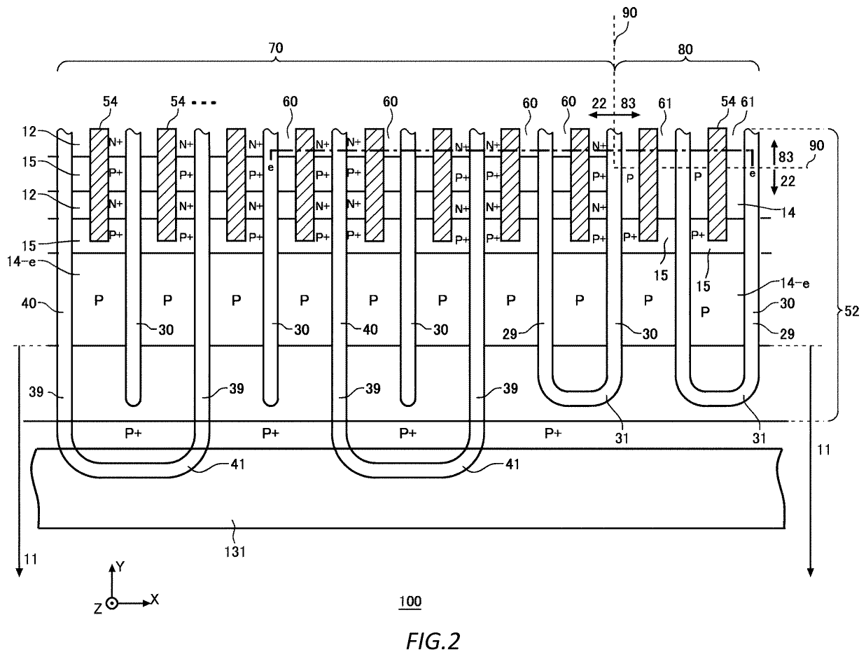

FIG. 2 illustrates an enlarged view of a region D in FIG. 1. The region D is a region including a transistor portion 70, a diode portion 80, and an active-side gate runner 131. The semiconductor device 100 in the present example includes a gate trench portion 40, a dummy trench portion 30, a well region 11, an emitter region 12, a base region 14, and a contact region 15 which are provided inside the upper surface side of the semiconductor substrate 10. Each of the gate trench portion 40 and the dummy trench portion 30 is an example of the trench portion. In addition, the semiconductor device 100 in the present example includes an emitter electrode 52 and the active-side gate runner 131 which are provided above the upper surface of the semiconductor substrate 10. The emitter electrode 52 and the active-side gate runner 131 are provided to be separate from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in the present example, a contact hole 54 is provided penetrating the interlayer dielectric film. In FIG. 2, each contact hole 54 is hatched with the diagonal lines.

The emitter electrode 52 is provided above the gate trench portion 40, the dummy trench portion 30, the well region 11, the emitter region 12, the base region 14, and the contact region 15. The emitter electrode 52 is in contact with the emitter region 12, the contact region 15, and the base region 14 at the upper surface of the semiconductor substrate 10, through the contact hole 54. In addition, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y-axis direction. The dummy conductive portion of the dummy trench portion 30 may not be connected to the emitter electrode 52 and a gate conductive portion, and may be controlled to be at potential different from potential of the emitter electrode 52 and potential of the gate conductive portion.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y-axis direction. The active-side gate runner 131 is not connected to the dummy conductive portion in the dummy trench portion 30.

The emitter electrode 52 is formed of a material containing metal. FIG. 2 illustrates a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided to overlap with the active-side gate runner 131. The well region 11 is provided to extend with a predetermined width even in a range that does not overlap with the active-side gate runner 131. The well region 11 in the present example is provided apart from an end of the contact hole 54 in the Y-axis direction toward the active-side gate runner 131 side. The well region 11 is a region of a second conductivity type having a higher doping concentration than that of the base region 14. The base region 14 in this example is a P-type, and the well region 11 is a P+ type.

Each of the transistor portion 70 and the diode portion 80 has a plurality of trench portions arrayed in the array direction. In the transistor portion 70 in the present example, one or more gate trench portions 40 and one or more dummy trench portions 30 are alternately provided along the array direction. In the diode portion 80 in the present example, the plurality of dummy trench portions 30 are provided along the array direction. In the diode portion 80 in the present example, the gate trench portion 40 is not provided.

The gate trench portion 40 in the present example may have two linear portions 39 extending along the extending direction perpendicular to the array direction (parts of a trench which are linear along the extending direction), and the edge portion 41 connecting the two linear portions 39. The extending direction in FIG. 2 is the Y-axis direction.

At least a part of the edge portion 41 is preferably provided in a curved shape in the top view. By connecting between end portions of the two linear portions 39 in the Y-axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or the plurality of dummy trench portions 30 may be provided. The dummy trench portion 30 may have a linear shape extending in the extending direction, or may have linear portions 29 and an edge portion 31 similar to the gate trench portion 40. The semiconductor device 100 shown in FIG. 2 includes both the linear dummy trench portion 30 having no edge portion 31 and the dummy trench portion 30 having the edge portion 31.

A diffusion depth of the well region 11 may be deeper than depths of the gate trench portion 40 and the dummy trench portion 30. The end portions in the Y-axis direction of the gate trench portion 40 and the dummy trench portion 30 are provided in the well region 11 in the top view. In other words, at the end portion of each trench portion in the Y-axis direction, a bottom portion of each trench portion in the depth direction is covered with the well region 11. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. A depth position of a lower end of the mesa portion is the same as a depth position of a lower end of the trench portion. The mesa portion in the present example is provided to extend in the extending direction (the Y-axis direction) along the trench, at the upper surface of the semiconductor substrate 10. In the present example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged to be closest to the active-side gate runner 131, in the base region 14 exposed to the upper surface of the semiconductor substrate 10, is set as a base region 14-e. In FIG. 2, the base region 14-e arranged at one end portion of each mesa portion in the extending direction is illustrated, but the base region 14-e is also arranged at another end portion of each mesa portion. Each mesa portion may be provided with at least one of the emitter region 12 of a first conductivity type, or the contact region 15 of the second conductivity type in a region sandwiched between the base regions 14-e in the top view. In the present example, the emitter region 12 is the N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed to the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X-axis direction. As an example, the contact region 15 and the emitter region 12 in the mesa portion 60 are alternately arranged along the extending direction of the trench portion (the Y-axis direction).

In another example, the contact region 15 and the emitter region 12 in the mesa portion 60 may be provided in a stripe shape along the extending direction of the trench portion (the Y-axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in the present example is provided above respective regions of the contact region 15, the base region 14, and the emitter region 12. In the diode portion 80, the contact region 15 may not be provided. The contact hole 54 is not provided in regions corresponding to the base region 14-e and the well region 11. The contact hole 54 may be arranged at the center of the mesa portion 60 in the array direction (the X-axis direction).

In the diode portion 80, a cathode region 83 is provided in a region adjacent to the lower surface of the semiconductor substrate 10. The cathode region 83 is a region in which the first cathode region of N+ type and the second cathode region of P+ type are periodically arranged. In FIG. 2, the first cathode region and the second cathode region are omitted. At the lower surface of the semiconductor substrate 10, the collector region 22 of P+ type may be provided in a region where the cathode region 83 is not provided. The cathode region 83 and the collector region 22 are provided between a lower surface 23 of the semiconductor substrate 10 and a buffer region 20. The cathode region 83 and the collector region 22 may be in contact with the lower surface 23 of the semiconductor substrate 10. In FIG. 2, a boundary 90 between the cathode region 83 and the collector region 22 is indicated by a dotted line.

The boundary 90 may match the boundary between the transistor portion 70 and the diode portion 80 in a top view from the upper surface 21. The position of the boundary 90 may be on a boundary between the transistor portion 70 and the diode portion 80, which is determined based on the structure of the upper surface 21 side of the semiconductor substrate 10. The boundary 90 in the X-axis direction may be positioned in a trench portion that is between the mesa portion 60 positioned closest to the diode portion 80 side of the transistor portion 70 and the mesa portion 61 positioned closest to the transistor portion 70 side of the diode portion 80. The boundary 90 in the X-axis direction may be on a center position of the trench in the X-axis direction. The trench may be a trench that is closest to the diode portion 80 among the trench portions that are in contact with the emitter region 12.

The boundary 90 in the Y-axis direction in a top view from the upper surface 21 may be positioned inward (on the +Y-axis direction side in the present example) relative to the end portion of the contact hole 54 in the Y-axis direction provided in the diode portion 80, and may further be positioned so as to overlap with the base region 14 that is exposed on the upper surface 21. In a top view from upper surface 21, a distance from the end portion of the contact hole 54 in the Y-axis direction provided in the diode portion 80 to the boundary 90 in the Y-axis direction may be equal to or more than a length corresponding to a half of the thickness of the semiconductor substrate 10, may be equal to or more than a length corresponding to 75% of the thickness of the semiconductor substrate 10, or may be equal to or more than a length corresponding to the thickness of the semiconductor substrate 10.

The first cathode region included in the cathode region 83 is arranged apart from the well region 11 in the Y-axis direction. With this configuration, the distance between the P type region (the well region 11) which has a relatively high doping concentration and which is formed to a deep position and the first cathode region of N+ type is ensured, so that the breakdown voltage can be improved. The end portion of the first cathode region in the Y-axis direction of the present example is arranged farther away from the well region 11 than the end portion of the contact hole 54 in the Y-axis direction. In another example, the end portion of the first cathode region in the Y-axis direction may be arranged between the well region 11 and the contact hole 54.

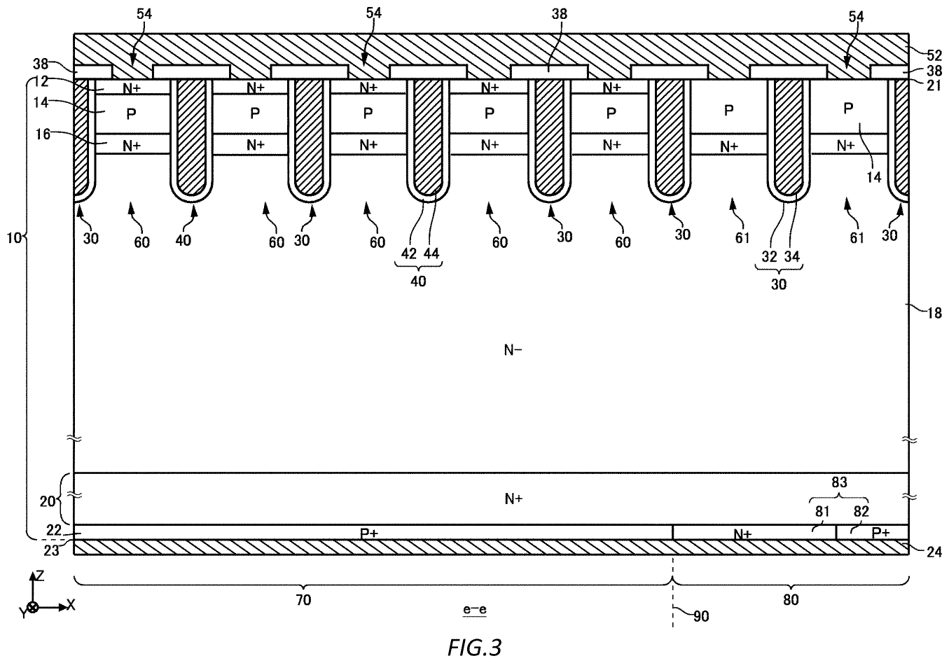

FIG. 3 is a view illustrating an example of a cross-section e-e in FIG. 2. The cross-section e-e is an XZ plane passing through the emitter region 12 and the cathode region 83. The cathode region 83 includes the first cathode region 81 of N+ type and the second cathode region 82 of P+ type. The semiconductor device 100 in the present example includes the semiconductor substrate 10, an interlayer dielectric film 38, the emitter electrode 52, and a collector electrode 24 in the cross section.

The interlayer dielectric film 38 is provided on the upper surface of the semiconductor substrate 10. The interlayer dielectric film 38 is a film including at least one layer of a dielectric film such as silicate glass to which an impurity such as boron or phosphorous is added, a thermal oxide film, or other dielectric films. The interlayer dielectric film 38 is provided with a contact hole 54 described with reference to FIG. 2.

The emitter electrode 52 is provided above the interlayer dielectric film 38. The emitter electrode 52 is in contact with the upper surface 21 of the semiconductor substrate 10 through the contact hole 54 of the interlayer dielectric film 38. The collector electrode 24 is provided at the lower surface 23 of the semiconductor substrate 10. The emitter electrode 52 and the collector electrode 24 are formed of a metal material such as aluminum. In the present specification, a direction (the Z-axis direction) in which the emitter electrode 52 is connected to the collector electrode 24 is referred to as the depth direction.

The semiconductor substrate 10 includes a drift region 18 of the N type or the N-type. The drift region 18 is provided in each of the transistor portion 70 and the diode portion 80.

In a mesa portion 60 of the transistor portion 70, the emitter region 12 of an N+ type and a base region 14 of a P-type are provided in order from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed to the upper surface 21 of the semiconductor substrate 10 and is provided in contact with the gate trench portion 40. The emitter region 12 may be in contact with the trench portions on both sides of the mesa portion 60. The emitter region 12 has a higher doping concentration than that of the drift region 18.

The base region 14 is provided below the emitter region 12. The base region 14 in the present example is provided in contact with the emitter region 12. The base region 14 may be in contact with the trench portions on both sides of the mesa portion 60.

An accumulation region 16 is provided below the base region 14. The accumulation region 16 is a region of the N+ type having a higher doping concentration than that of the drift region 18. That is, the accumulation region 16 has a higher donor concentration than that of the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover an entire lower surface of the base region 14 in each mesa portion 60.

A mesa portion 61 of the diode portion 80 is provided with the base region 14 of the P− type in contact with the upper surface 21 of the semiconductor substrate 10. The base region 14 of the diode portion 80 functions as an anode region of the diode portion 80. The drift region 18 is provided below the base region 14. In the mesa portion 61, the accumulation region 16 may be provided below the base region 14.

In each of the transistor portion 70 and the diode portion 80, the buffer region 20 of the N+ type may be provided below the drift region 18. A doping concentration of the buffer region 20 is higher than the doping concentration of the drift region 18. The buffer region 20 may have a concentration peak having a higher doping concentration than that of the drift region 18. A doping concentration at a concentration peak refers to a doping concentration at a local maximum of the concentration peak. In addition, as the doping concentration of the drift region 18, an average value of doping concentrations in a region where doping concentration distribution is substantially flat may be used.

The buffer region 20 may have two or more concentration peaks in the depth direction (the Z-axis direction) of the semiconductor substrate 10. The concentration peak of the buffer region 20 may be provided, for example, at the same depth position as that of a chemical concentration peak of hydrogen (a proton) or phosphorous. The buffer region 20 may function as a field stop layer which prevents a depletion layer widening from a lower end of the base region 14 from reaching the collector region 22 and the cathode region 83.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

In the diode portion 80, the first cathode region 81 and the second cathode region 82 are provided below the buffer region 20. In the example of FIG. 3, the first cathode region 81 is in contact with the collector region 22, although the second cathode region 82 may be in contact with the collector region 22.

A donor concentration of the first cathode region 81 is higher than a donor concentration of the drift region 18. The donor of the first cathode region 81 is arsenic, hydrogen, or phosphorus, for example. The acceptor of the second cathode region 82 is boron, indium, or aluminum, for example. The acceptor concentration of the second cathode region 82 may be higher than the acceptor concentration of the base region 14. The acceptor concentration of the second cathode region 82 may be the same as or different from the acceptor concentration of the collector region 22. It should be noted that an element serving as a donor and an acceptor in each region is not limited to the example described above.

When the acceptor concentrations of the second cathode region 82 and the collector region 22 are the same, and when the second cathode region 82 and the collector region 22 are in contact with each other, the trench portion between the mesa portion 60 in which the emitter region 12 is arranged and the mesa portion 61 in which no emitter region 12 is arranged may be defined as the boundary position between the second cathode region 82 and the collector region 22. More specifically, the center position of the trench portion in the X-axis direction may be defined as the boundary position between the second cathode region 82 and the collector region 22.

The collector region 22 and the cathode region 83 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided at the upper surface 21 side of the semiconductor substrate 10. Each trench portion passes through the base region 14, and is provided from the upper surface 21 of the semiconductor substrate 10 to a region below the base region 14. In a region where at least any of the emitter region 12, the contact region 15, or the accumulation region 16 is provided, each trench portion also passes through the doping regions of these. A structure in which the trench portion passes through the doping region is not limited to a structure which is made by forming the doping region and then forming the trench portion in order. A structure in which the trench portion is formed and then the doping region is formed between the trench portions is also included in the structure in which the trench portion passes through the doping region.

As described above, the transistor portion 70 is provided with the gate trench portion 40 and the dummy trench portion 30. The diode portion 80 is provided with the dummy trench portion 30, and is not provided with the gate trench portion 40. The boundary between the diode portion 80 and the transistor portion 70 in the X-axis direction, in the present example, is a boundary between the cathode region 83 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover an inner wall of the gate trench. The gate dielectric film 42 may be formed by oxidizing or nitriding a semiconductor on the inner wall of the gate trench. The gate conductive portion 44 is provided farther inward than the gate dielectric film 42 inside the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as that of the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided to cover an inner wall of the dummy trench. The dummy conductive portion 34 is provided inside the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portion 40 and the dummy trench portion 30 in the present example are covered with the interlayer dielectric film 38 on the upper surface 21 of the semiconductor substrate 10. It should be noted that bottom portions of the dummy trench portion 30 and the gate trench portion 40 may have curved surfaces which are convex downward (curved shapes in the cross sections).

By the diode portion 80 including the second cathode region 82, holes in the drift region 18 or the like can be extracted via the second cathode region 82. Thus, accumulation of holes in the diode portion 80 in the ON state can be suppressed, and the loss during reverse recovery can be reduced. Also, by the provision of the second cathode region 82, the forward voltage in the diode portion 80 in the ON state varies. The characteristics of the reverse recovery loss, the forward voltage, and the like can be adjusted by adjusting the arrangement of the first cathode region 81 and the second cathode region 82.

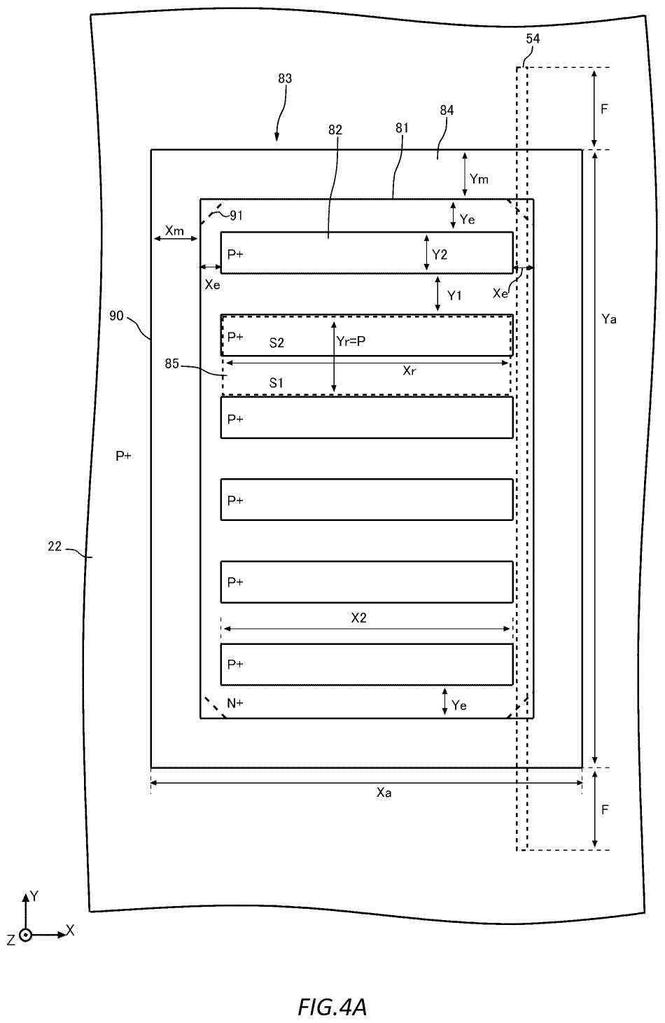

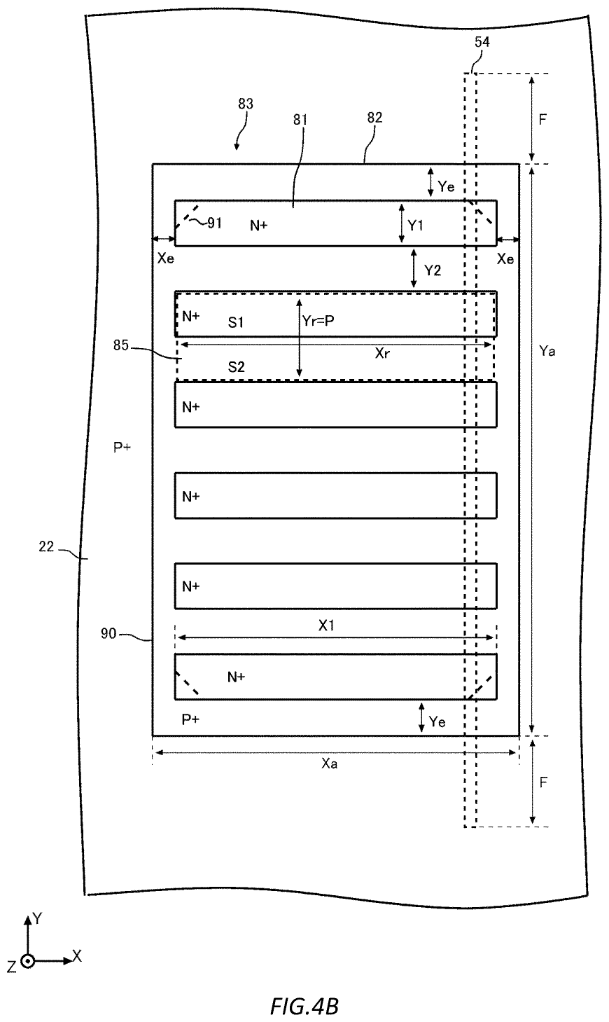

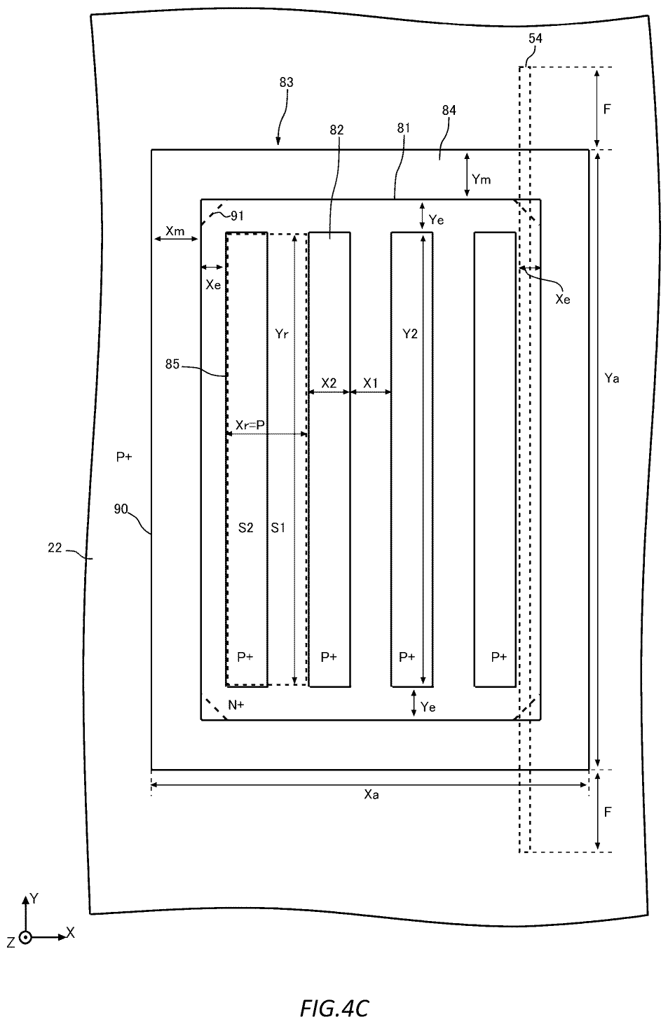

FIG. 4A shows an exemplary arrangement of the first cathode region 81 and the second cathode region 82 on the lower surface 23 of the semiconductor substrate 10. FIG. 4A shows an exemplary arrangement of the first cathode region 81 and the second cathode region 82 in one diode portion 80. All the diode portions 80 may include the arrangement as shown in FIG. 4A. In FIG. 4A, the collector region 22 surrounding the diode portion 80 is also shown. In addition, the a position of one contact hole 54 among the contact holes 54 provided on the upper surface 21 is shown by a dotted line.

The first cathode region 81 and the second cathode region 82 of the present example are provided alternately in the first direction. The first direction in the example of FIG. 4A is the Y-axis direction. The structure in which the first cathode region 81 and the second cathode region 82 are alternately arranged in the first direction is referred to as the repetition structure 85. For example, the repetition structure 85 includes only one pair of the first cathode region 81 and the second cathode region 82 alternately arranged in the first direction. In the diode portion 80, at least two repetition structures 85 are provided in contact with each other in the first direction. When the first cathode region 81 and the second cathode region 82 are alternately provided in a plurality of directions, at least two repetition structures 85 are provided in contact with each other in each direction in the diode portion 80.

In the present example, the first cathode region 81 included in the repetition structure 85 has a length in the X-axis direction that is longer than a length in the Y-axis direction. The second cathode region 82 included in the repetition structure 85 also has a length in the X-axis direction that is longer than a length in the Y-axis direction.

The length of one cathode region 83 in the X-axis direction is denoted by Xa, and the length of one cathode region 83 in the Y-axis direction is denoted by Ya. The length of one repetition structure 85 in the X-axis direction is denoted by Xr, and the length of one repetition structure 85 in the Y-axis direction is denoted by Yr. In the present specification, the length (Yr in the present example) of the repetition structure 85 in the direction in which the first cathode region 81 and the second cathode region 82 are alternately arranged (the Y-axis direction in FIG. 4A) is referred to as repetition pitch P of the first cathode region 81 and the second cathode region 82. When the first cathode region 81 and the second cathode region 82 are alternately provided in a plurality of directions, each length of the repetition structure 85 in each direction is the repetition pitch P. When there is a plurality of repetition structures 85 of different lengths in one direction, an average value of the lengths of the plurality of repetition structures 85 may be defined as the repetition pitch P in that direction.

Also, an area of the first cathode region 81 included in one repetition structure 85 is denoted by S1, and the area of the second cathode region 82 is denoted by S2. In the present specification, a ratio of the area of the second cathode region 82 (S2/S1+S2) relative to the sum of the areas of the first cathode region 81 and the second cathode region 82 (S1+S2) included in one repetition structure 85 is referred to as the area ratio R. When there is a plurality of repetition structures 85 of different area ratios, an average value of the area ratios of the plurality of repetition structures 85 included in the cathode region 83 may be defined as the area ratio R.

In the example of FIG. 4A, the first cathode region 81 and the second cathode region 82 are alternately arranged in the Y-axis direction. When both the first cathode region 81 and the second cathode region 82 are provided continuously from one end portion to another end portion of the cathode region 83 in the X-axis direction, the length Xa of the cathode region 83 in the X-axis direction is defined as the length Xr of the repetition structure 85 in the X-axis direction.

The cathode region 83 may include a margin region 84. The margin region 84 is a region from the boundary 90 to the first cathode region 81. The margin region 84 may have the same conductivity type as the second cathode region 82. The margin region 84 may have the same doping concentration distribution as the second cathode region 82. The length of the margin region 84 in the X-axis direction is denoted by Xm, and the length of the margin region 84 in the Y-axis direction is denoted by is denoted by Ym.

As shown in FIG. 4A, when the length of one of the first cathode region 81 or the second cathode region 82 in the X-axis direction is shorter than the length Xa of the cathode region 83 in the X-axis direction, the length Xr of the repetition structure 85 in the X-axis direction is defined as being the same as the length of the shorter one of first cathode region 81 or the second cathode region 82 in the X-axis direction. In the example of FIG. 4A, the length X2 of the second cathode region 82 is less than the length Xa of the cathode region 83. In this case, the length X2 of the second cathode region 82 is defined as the length Xr of the repetition structure 85.

In the present example, the length Yr of the repetition structure 85 in the Y-axis direction is the sum of a length Y1 of one first cathode region 81 in the Y-axis direction and a length Y2 of one second cathode region 82 in the Y-axis direction. The repetition pitch P in the present example is Y1+Y2. Also, the area ratio R is S2/(S1+S2)=Y2/(Y1+Y2). By adjusting the repetition pitch P and the area ratio R to be in a predetermine range, the characteristics of the forward voltage, the reverse recovery loss, and the like can be adjusted. The ranges in which the repetition pitch P and the area ratio R should be adjusted will be described below.

The first cathode region 81 having the length Xe may be arranged in contact with each of both ends of the second cathode region 82 in the X-axis direction. The length Xe is 0 μm or more.

The length Xe may be less than the length Xr, may be less than the length Y1, or may be less than the length Y2. The length Xe may be equal to or more than one time, equal to or more than twice, equal to or more than five times, equal to or more than ten times, or equal to or more than twenty times the width of the mesa portion 61 in the X-axis direction. The length Xe may be equal to or less than 50 times, or may be equal to or less than 30 times the width of the mesa portion 61 in the X-axis direction. By including the first cathode region 81 of the length Xe in contact with both ends of the second cathode region 82, an electrical interference due to hole inflow between the diode portion 80 and the transistor portion 70 can be suppressed.

The length of the first cathode region 81 or the second cathode region 82 in the Y-axis direction arranged on both ends of the cathode region 83 in the Y-axis direction is denoted by Ye. In the example of FIG. 4A, the first cathode region 81 is arranged on both ends of the cathode region 83. The length Ye is 0 μm or more. The length Ye may be less than the length Yr, may be less than the length Y1, or may be less than the length Y2. By including the first cathode region 81 or the second cathode region 82 of the length Ye in both ends of the cathode region 83, carrier behavior in the end portion of the diode portion 80 in the Y-axis direction can be relatively uniform.

In the Y-axis direction, a length of the contact hole 54 which protrudes from the boundary 90 is denoted by F. The length Fis 0 μm or more. The length F may be less than the length Yr, may be less than the length Y1, or may be less than the length Y2. By including the length F, carrier crowding in the end portion of the contact hole 54 in the Y-axis direction can be suppressed.

In a top view of the first cathode region 81, a corner that is closest to the transistor portion 70 side in the X-axis direction and that is at the outermost position in the Y-axis direction may have a chamfered portion 91 which has been chamfered. The chamfered portion 91 may be a region in which the width of the first cathode region 81 in the Y-axis direction decreases toward the transistor portion 70. The corner of the first cathode region 81 that has been chamfered by the chamfered portion 91 may be provided with the margin region 84 or the second cathode region 82 instead of the first cathode region 81. In the present example, a portion indicated by a dashed line at the corner may be defined as the chamfered portion 91 and may be defined as the boundary between the first cathode region 81 and the margin region 84. This configuration has an effect to prevent crowding of the electronic current at the corner of the first cathode region 81 during reverse recovery.

FIG. 4B shows another exemplary arrangement of the first cathode region 81 and the second cathode region 82 in one cathode region 83. In the present example, the first cathode region 81 and the second cathode region 82 in FIG. 4A are switched with each other. Again in the present example, the repetition pitch P is Y1+Y2 and the area ratio R is S2/(S1+S2)=Y2/(Y1+Y2). Also, the lengths Xe, Ye, and F may be the same as or different from those in the example of FIG. 4A. The margin region 84 may be or may not be provided. The margin region 84 of the present example is zero in both the length Xm and the length Ym.

FIG. 4C shows another exemplary arrangement of the first cathode region 81 and the second cathode region 82 in one cathode region 83. FIG. 4C is different from FIG. 4A in that the first cathode region 81 and the second cathode region 82 have their longitudinal direction in the Y-axis direction and are alternately arrayed in the X-axis direction. Their dimensions, repetition pitches P, area ratios R, or the like may be the same as those in FIG. 4A. Note that the lengths X1, X2, and Xr in the example of FIG. 4C correspond to the lengths Y1, Y2, and Yr in the example of FIG. 4A. Also, the lengths Y2 and Yr in the example of FIG. 4C correspond to the lengths X2 and Xr in the example of FIG. 4A.

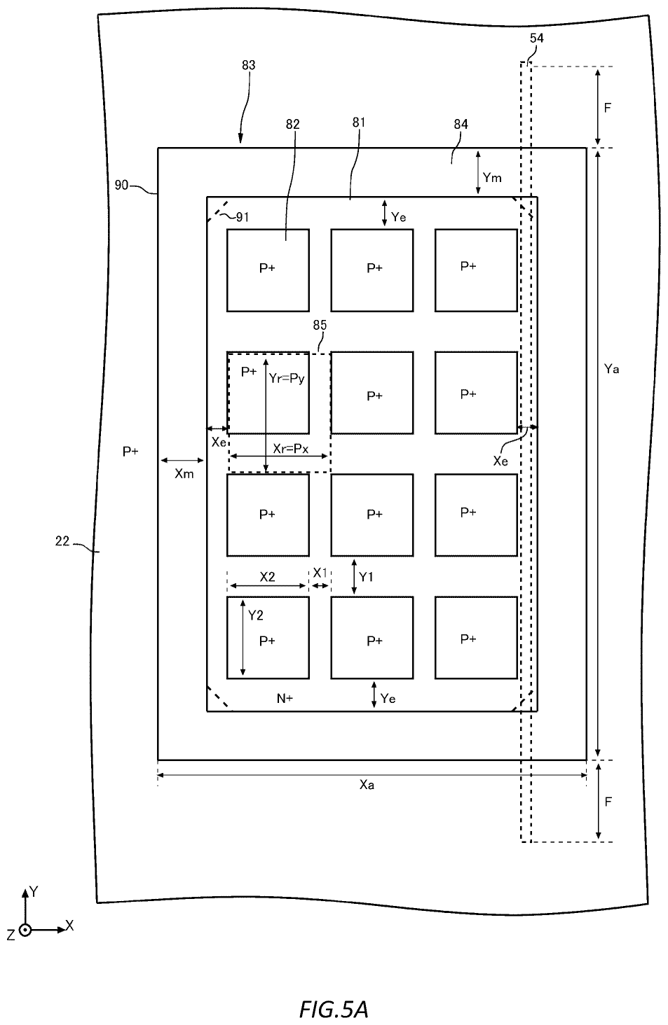

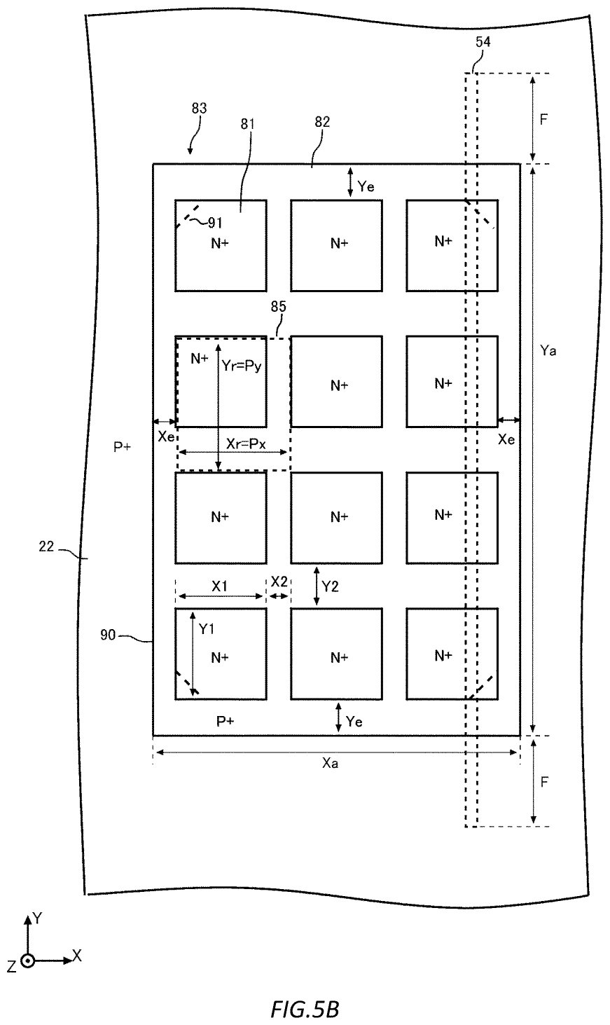

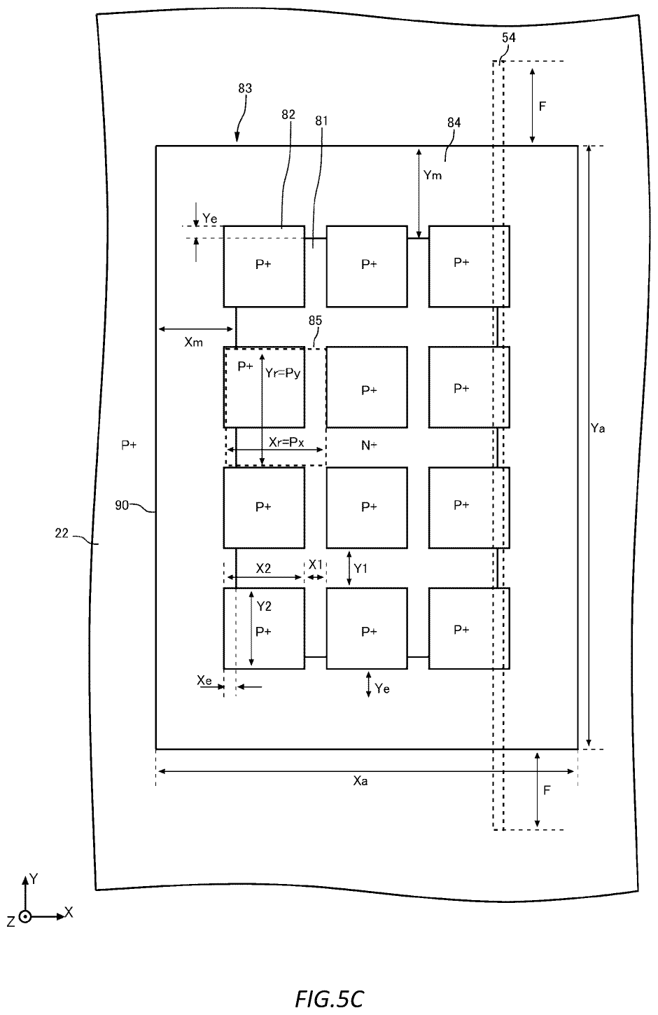

FIG. 5A shows another exemplary arrangement of the first cathode region 81 and the second cathode region 82 in one diode portion 80. The first cathode region 81 and the second cathode region 82 of the present example are provided alternately in a plurality of directions. In the example of FIG. 5A, the plurality of directions are the X-axis direction and the Y-axis direction. In the present example, the structure in which the first cathode region 81 and the second cathode region 82 are alternately arranged in both X-axis direction and the Y-axis direction is referred to as the repetition structure 85. In the diode portion 80, at least two repetition structures 85 are provided in contact with each other in the X-axis direction, and also at least two repetition structures 85 are provided in contact with each other in the Y-axis direction. For example, the repetition structure 85 has such a rectangular shape as to include only one pair of the first cathode region 81 and the second cathode region 82 alternately arranged in the X-axis direction and include only one pair of the first cathode region 81 and the second cathode region 82 alternately arranged in the Y-axis direction.

In the present example, the second cathode regions 82 of a rectangular shape are arranged at a predetermined interval in both the X-axis direction and the Y-axis direction in the inside of the cathode region 83. In the cathode region 83, a region other than the second cathode regions 82 is the first cathode region 81.

The length of one second cathode region 82 in the X-axis direction is denoted by X2, and the length of one second cathode region 82 in the Y-axis direction is denoted by Y2. In the X-axis direction, the length of the first cathode region 81 sandwiched between the second cathode regions 82 is denoted by X1. In the Y-axis direction, the length of the first cathode region 81 sandwiched between the second cathode regions 82 is denoted by Y1.

The length Xr of the repetition structure 85 of the present example in the X-axis direction is X1+X2 and the length Yr of the repetition structure 85 of the present example in the Y-axis direction is Y1+Y2. The first cathode region 81 and the second cathode region 82 of the present example are arranged at the repetition pitch Px=Xr in the X-axis direction and arranged at the repetition pitch Py=Yr in the Y-axis direction. In the present specification, when a range or value of the repetition pitch is described, at least one of the repetition pitch Px or repetition pitch Py may have the described range or value, or both the repetition pitch Px and the repetition pitch Py may have the described range or value. Also, the repetition pitch Px and Py may be the same value. The area ratio R of the present example is (X2×Y2)/(Xr×Yr)=(X2×Y2)/((X1+X2)×(Y1+Y2)).

The lengths Xe, Ye, and F may be the same as or different from those in the example of FIG. 4A. The length Xe of the present example may be X2/2 or more and X1/2 or less. The length Ye of the present example may be Y2/2 or more and Y1/2 or less.

FIG. 5B shows another exemplary arrangement of the first cathode region 81 and the second cathode region 82 in one cathode region 83. In the present example, the first cathode region 81 and the second cathode region 82 in FIG. 5A are switched with each other. Again in the present example, the repetition pitch Px is X1+X2 and the repetition pitch Py is Y1+Y2. The area ratio R is 1−((X1×Y1)/(Xr×Yr))=1−((X1×Y1)/((X1+X2)×(Y1+Y2))). Also, the lengths Xe, Ye, and F may be the same as or different from those in the example of FIG. 5A. The length Xe of the present example may be X2/2 or more and X1/2 or less. The length Ye of the present example may be Y2/2 or more and Y1/2 or less.

FIG. 5C shows another exemplary arrangement of the first cathode region 81 and the second cathode region 82 in one cathode region 83. In the present example, the second cathode region 82 of FIG. 5A protrudes further to the transistor portion 70 side in the X-axis direction relative to the first cathode region 81 and to the outside in the Y-axis direction relative to the first cathode region 81. Accordingly, it is different from FIG. 5A in that the first cathode region 81 has no corner. Other than that, the present example may be the same as that of FIG. 5A. All the end portions of the first cathode region 81 in the X-axis direction may be arranged inward relative to the end portions of the second cathode region 82. All the end portions of the first cathode region 81 in the Y-axis direction may be arranged inward relative to the end portions of the second cathode region 82. Inward refers to a part that is closer to the center of the cathode region 83.

The second cathode region 82 of the present example protrudes by the length Xe in the X-axis direction and protrudes by the length Ye in the Y-axis direction from the end portion of the first cathode region 81. The length Xe may be a half or less or ¼ or less of the length X2 of the second cathode region 82. The length Xe may be 1/10 or more of the length X2. The length Ye may be a half or less or ¼ or less of the length Y2 of the second cathode region 82. The length Ye may be 1/10 or more of the length Y2.

As shown in FIG. 5C, the repetition structures 85 arranged outside and the repetition structures 85 arranged inside may have a different structure. More specifically, the repetition structure 85 which includes the end portion of the first cathode region 81 has a different arrangement pattern of the first cathode region 81 compared to other repetition structures 85. In the present example, the repetition structure 85 may be determined based on the pattern of the second cathode region 82 and the region (margin region 84 and the first cathode region 81) other than the second cathode region 82. That is, in determining the repetition structure 85, the margin region 84 may be regarded as the first cathode region 81.

A portion of the second cathode region 82 that protrudes to the outside of the end portion of the first cathode region 81 may be regarded as the collector region 22. This portion may have the same doping concentration as the collector region 22.

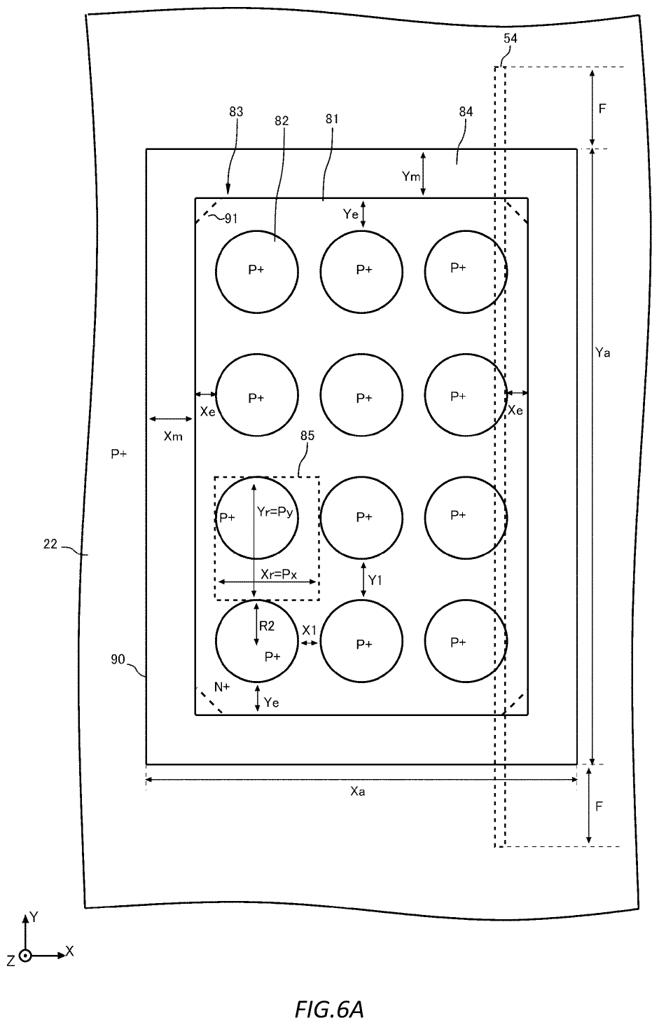

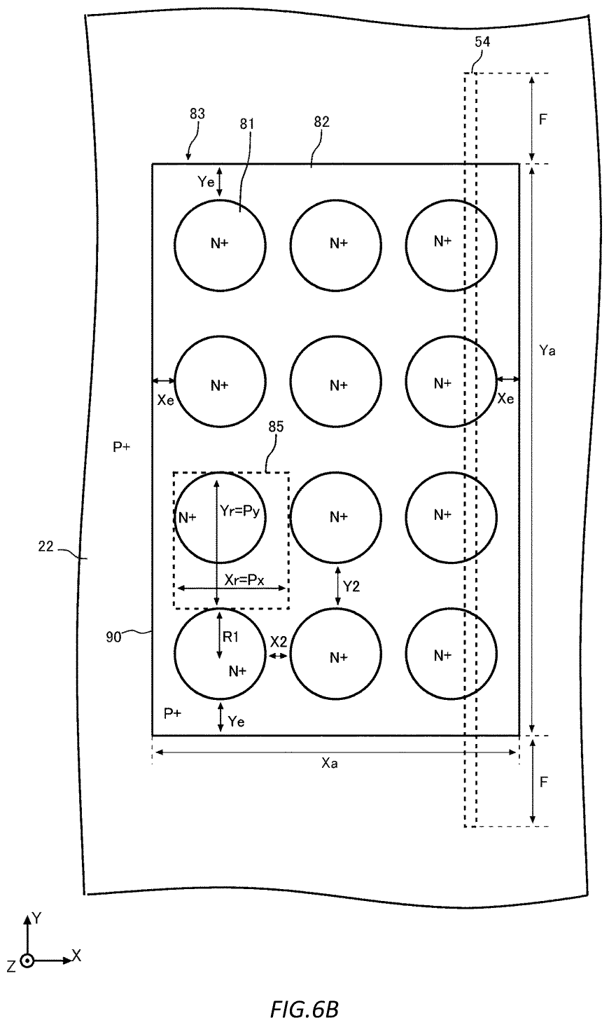

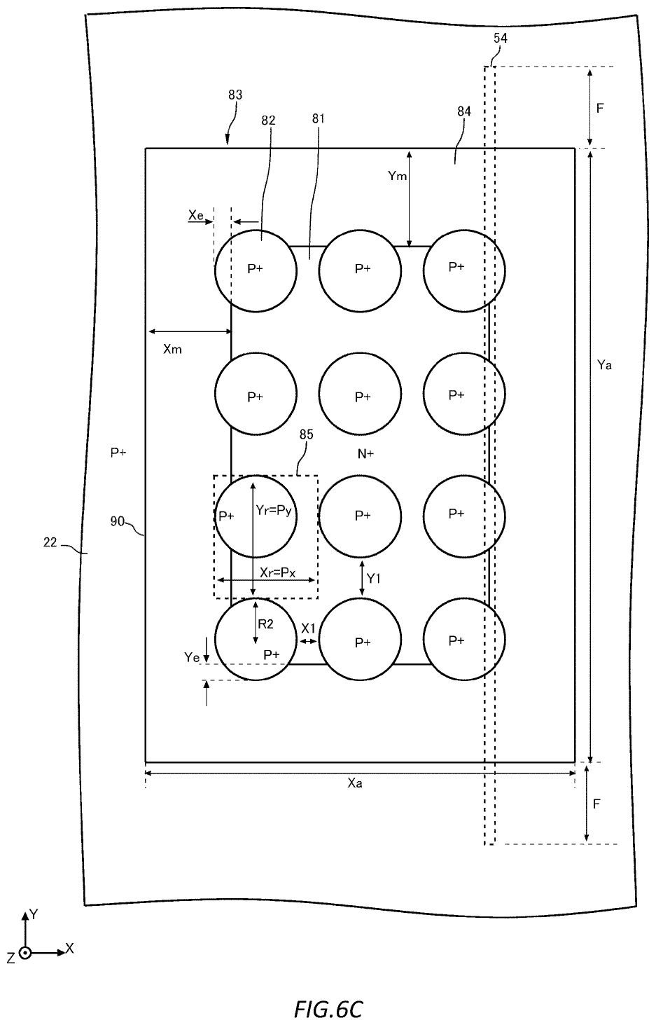

FIG. 6A shows another exemplary arrangement of the first cathode region 81 and the second cathode region 82 in one diode portion 80. In the present example, the shape of the second cathode region 82 is different from that of the example in FIG. 5A. Other structures are similar to those in FIG. 5A. The shape of the second cathode region 82 in the present example is a circle. Note that the shape of the second cathode region 82 is not limited to a rectangle or circle.

The radius of one second cathode region 82 is denoted by R2. In the X-axis direction, a minimum value of the length of the first cathode region 81 sandwiched between the second cathode regions 82 is denoted by X1. In the Y-axis direction, a minimum value of the length of the first cathode region 81 sandwiched between the second cathode regions 82 is denoted by Y1.

The length Xr of the repetition structure 85 of the present example in the X-axis direction is X1+2×R2 and the length Yr of the repetition structure 85 of the present example in the Y-axis direction is Y1+2×R2. The first cathode region 81 and the second cathode region 82 of the present example are arranged at the repetition pitch Px=Xr in the X-axis direction and arranged at the repetition pitch Py=Yr in the Y-axis direction. The area ratio R of the present example is (π×R2²)/(Xr×Yr)=(π×R22)/((2×R2+X1)×(2×R2+Y1)).

The lengths Xe, Ye, and F may be the same as or different from those in the example of FIG. 5A. The length Xe of the present example may be X1 or more and R2 or less. The length Ye of the present example may be Y1 or more and R2 or less.

FIG. 6B shows another exemplary arrangement of the first cathode region 81 and the second cathode region 82 in one cathode region 83. In the present example, the first cathode region 81 and the second cathode region 82 in FIG. 6A are switched with each other. The radius of the first cathode region 81 is denoted by R1. The repetition pitch Px of the present example is X2 +2×R1 and the repetition pitch Py is Y2+2×R1. The area ratio R is 1−(π×R12)/(Xr×Yr)=1−(π×R1²)/((2×R1+X2)×(2×R1+Y2)). Also, the lengths Xe, Ye, and F may be the same as or different from those in the example of FIG. 6A. The length Xe of the present example may be X2/2 or more and R1 or less. The length Ye of the present example may be Y2/2 or more and R1 or less.

FIG. 6C shows another exemplary arrangement of the first cathode region 81 and the second cathode region 82 in one cathode region 83. In the present example, the second cathode region 82 of FIG. 6A protrudes further to the transistor portion 70 side in the X-axis direction relative to the first cathode region 81 and to the outside in the Y-axis direction relative to the first cathode region 81. Accordingly, it is different from FIG. 6A in that the first cathode region 81 has no corner. Other than that, the present example may be the same as that of FIG. 6A. The arrangement of the end portion of the first cathode region 81 may be similar to the example of FIG. 5C. Also, the determination of the repetition structure 85 may be made in a similar manner to the example of FIG. 5C.

The examples of FIGS. 5A, 5B, 5C, 6A, 6B, and 6C include the repetition structures 85 arranged periodically along a square lattice (or a rectangular lattice), but they are not limited thereto. The repetition structures 85 may be arranged periodically along a triangular lattice or may be arranged periodically along a honeycomb lattice.

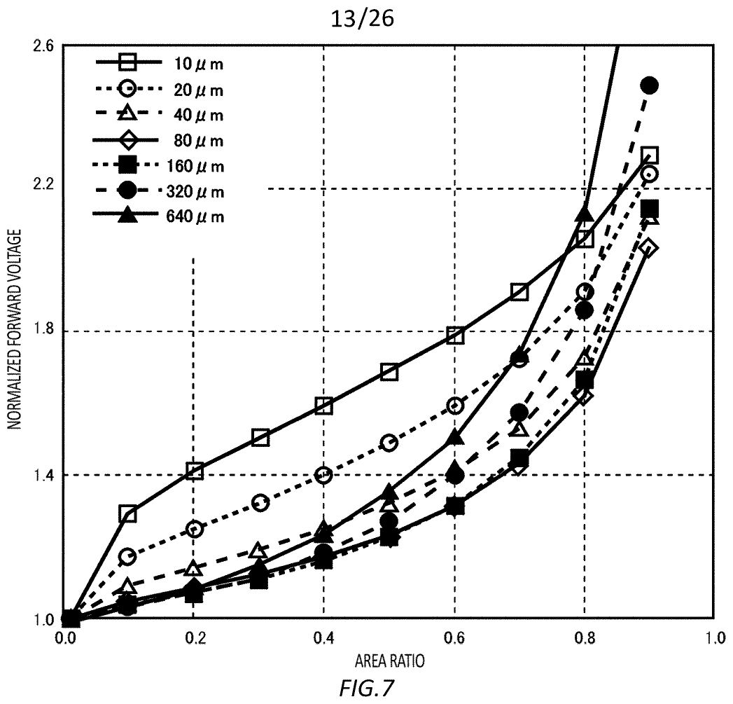

FIG. 7 shows a relationship between the area ratio R and the forward voltage in the diode portion 80. The forward voltage is normalized by setting the voltage at R=0 to 1. In other drawings, the forward voltage may also be normalized in a similar manner. FIG. 7 shows a characteristic of each sample obtained by setting the repetition pitch P in the example shown in FIG. 4A to 10 μm, 20 μm, 40 μm, 80 μm, 160 μm, 320 μm, or 640 μm. Note that the example shown in FIG. 4B also exhibits similar characteristics.

As the area ratio R increases, the area of the second cathode region 82 increases. Accordingly, in the ON state of the diode portion 80, the amount of hole extracted from the cathode region 83 increases, and the on-resistance of the diode portion 80 becomes larger. Thus, as the area ratio R increases, the forward voltage increases. In particular, when the area ratio R is larger than 0.8, the forward voltage rapidly increases. Thus, the area ratio R is preferably 0.8 or less. The area ratio R may be 0.7 or less, or may be 0.6 or less. Meanwhile, when the second cathode region 82 is too small, the effect of reducing the reverse recovery loss is decreased. The area ratio R is preferably 0.1 or more. The area ratio R may be 0.15 or more, or may be 0.2 or more.

As shown in FIG. 7, it is shown that the forward voltage tends to decrease as the repetition pitch P increases from 10 μm to 80 μm. When the repetition pitch P is small, the length Y1 in the first cathode region 81 also becomes relatively small. When the length Y1 of the first cathode region 81 is small, a distance from holes existing above the first cathode region 81 to the second cathode region 82 cannot be ensured, and the holes existing above the first cathode region 81 are easily extracted to the second cathode region 82. Thus, the diode portion 80 becomes difficult to turn on, and the forward voltage is increased. It is considered that as the repetition pitch P increases, the diode portion 80 becomes easier to turn on, and the forward voltage is decreased.

On the other hand, it is shown that when the repetition pitch P increases from 160 μm to 640 μm, the forward voltage tends to increase. When the repetition pitch P is relatively small, the length Y2 of the second cathode region 82 is also relatively small, so that electrons injected from the first cathode region 81 during the on-operation of the diode portion 80 spread more easily above the entire second cathode region 82. Thus, the region above the second cathode region 82 also operates as a diode. When the repetition pitch P is increased to a certain degrees, electrons from the first cathode region 81 cannot be spread in some regions above the second cathode region 82. Thus, a part of the region above the second cathode region 82 does not operate as the diode. As the repetition pitch P is increased, the region which does not operate as the diode also becomes larger, and the forward voltage is increased. Thus, it is considered that the forward voltage is increased when the repetition pitch P is increased from 160 μm to 640 μm, as shown in FIG. 7.

As described above, while the repetition pitch P is increased from 10 μm to 80 μm, the forward voltage is decreased, whereas while the repetition pitch P is increased from 160 μm to 640 μm, the forward voltage is increased. Thus, the forward voltage is relatively stable when the repetition pitch P is in a range of 40 μm or more and 200 μm or less. It is considered that in the range of the repetition pitch P of 40 μm or more and 200 μm or less, a good balance is achieved between the effect of appropriately maintaining the concentration of minority carriers (holes in the present example) in a drift region 18 from the first cathode region 81 to the upper surface 21 side and the reduction effect of the carrier concentration due to short circuit of the minority carriers in the second cathode region 82, when the carrier lifetime is relatively long such as 1 μs or more, and as a result, the forward voltage exhibits an appropriate value and becomes relatively stable. The repetition pitch P is preferably 40 μm or more and 200 μm or less. By setting the repetition pitch P to 40 μm or more and 200 μm or less, variation in the forward voltage caused by manufacturing variation of the repetition pitch P or the like can be suppressed. Then, by adjusting the area ratio R, the forward voltage can be adjusted to a predetermined value.

The repetition pitch P may be 80 μm or more. The repetition pitch P may be 160 μm or less. As shown in FIG. 7, the forward voltage exhibits a similar characteristic between the repetition pitch P of 80 μm and the repetition pitch P of 160 μm. This allows the variation in the forward voltage to be further reduced. From the result shown in FIG. 7, it is presumed that the repetition pitch P has the local minimum value from the repetition pitch P of 80 μm to the repetition pitch P of 160 μm. The repetition pitch P may be 100 μm or more. The repetition pitch P may be 130 μm or less.

When the area ratio R is 0.6 or less, the forward voltages are approximately the same between the examples of the repetition pitch P of 80 μm and the repetition pitch P of 160 μm. The area ratio R may be 0.6 or less. The repetition pitch P in this case may be 80 μm or more and 160 μm or less.

When the area ratio R is 0.5 or less, the variation in the forward voltage is relatively small in a range of the repetition pitch P of 40 μm or more. When each of the first cathode region 81 and the second cathode region 82 included in the repetition structure 85 as shown in FIG. 4A has a longitudinal length in the longitudinal direction (X-axis direction) that is different from the first direction (Y-axis direction), the area ratio R may be 0.5 or less. The area ratio R may be 0.4 or less. The repetition pitch P may be 40 μm or more and 200 μm or less.

In other examples, the repetition pitch P may be 40 μm or more and 80 μm or less. In this region, as the repetition pitch P increases, the forward voltage increases. Thus, by adjusting the repetition pitch P, the forward voltage can be adjusted.

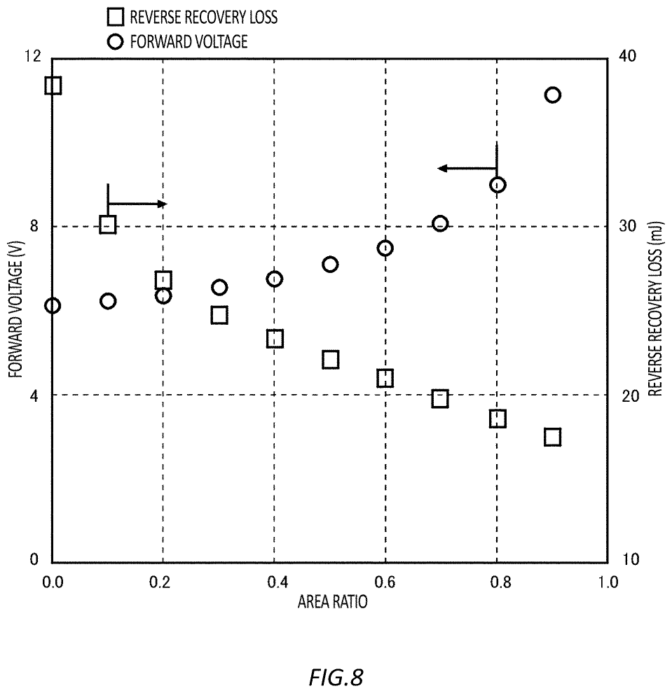

FIG. 8 shows a relationship between the forward voltage and a reverse recovery loss relative to the area ratio R. The diode portion 80 of FIG. 8 has the structure shown in FIG. 5A, and its repetition pitch P is 80 μm. The forward voltage is at the forward current density of 1800 A/cm², which is a relatively high current density.

As shown in FIG. 8, as the area ratio R increases, the reverse recovery loss decreases and the forward voltage increases. The upper limit value of the area ratio R may be determined based on the characteristic of the area ratio-forward voltage. For example, the upper limit value (0.8 in FIG. 8) of the area ratio R may be set so that the forward voltage is a tolerance value or less. The lower limit value of the range of the area ratio R may be determined based on the characteristic of the area ratio-reverse recovery loss. For example, the lower limit value (0.1 in FIG. 8) of the area ratio R may be set so that the reverse recovery loss is a tolerance value or less.

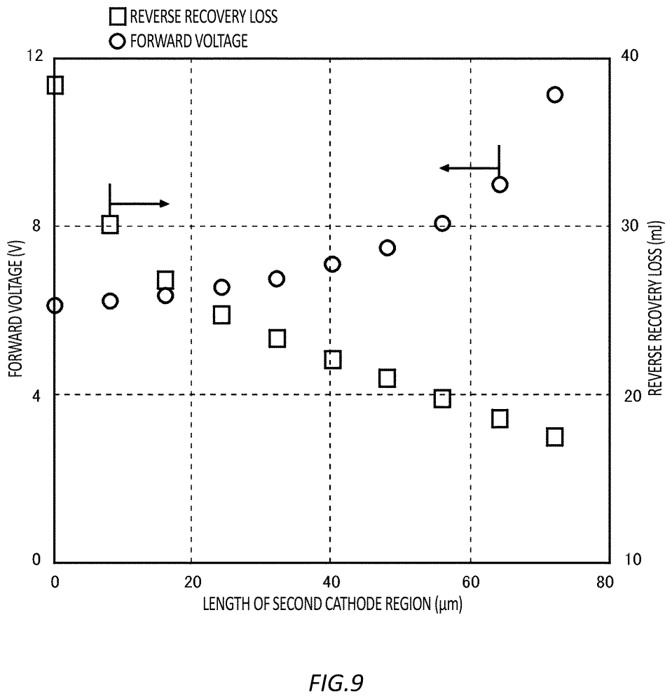

FIG. 9 shows a relationship between the forward voltage and the reverse recovery loss relative to a length Y2 of the second cathode region 82 in the first direction. The diode portion 80 of FIG. 9 has the structure shown in FIG. 5A, and its repetition pitch P is 80 μm.

As shown in FIG. 9, as the length Y2 increases, the reverse recovery loss decreases and the forward voltage increases. The upper limit value of the length Y2 may be determined based on the characteristic of the length Y2-forward voltage. For example, the upper limit value of the length Y2 may be set so that the forward voltage is a tolerance value or less. The length Y2 may be 65 μm or less, may be 60 μm or less, or may be 55 μm or less. The lower limit value of the length Y2 may be determined based on the characteristic of the length Y2-reverse recovery loss. For example, the lower limit value of the length Y2 may be set so that the reverse recovery loss is a tolerance value or less. The length Y2 may be 10 μm or more, 15 μm or more, or 20 μm or more.

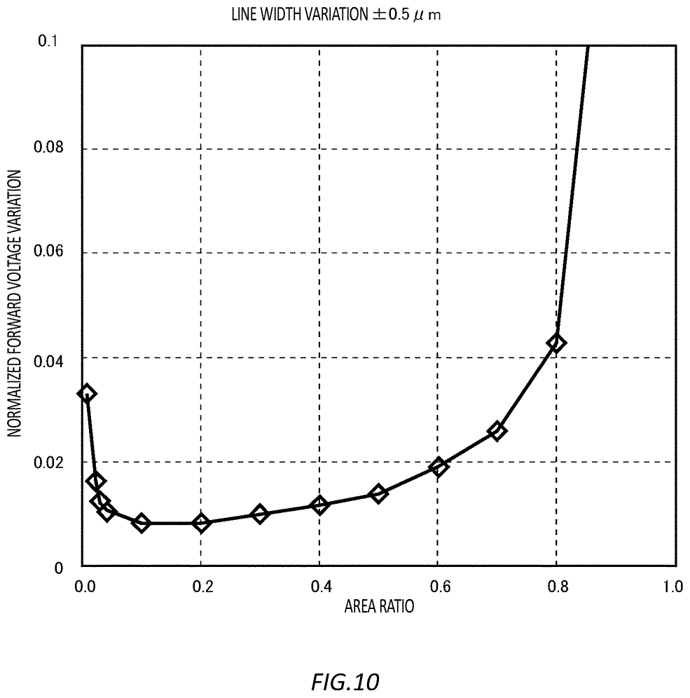

FIG. 10 shows a relationship between the magnitude of forward voltage variation due to patterning variation in the manufacturing process and the area ratio R. The diode portion 80 of FIG. 10 has the structure shown in FIG. 5A, and its repetition pitch P is 80 μm.

In the example of FIG. 10, the variation in patterning is assumed to be ±0.5 μm. That is, the length Y1 of the first cathode region 81 and the length Y2 of the second cathode region 82 each include the variation of ±0.5 μm. Also, the magnitude of the variation in the forward voltage is normalized by setting the magnitude of the forward voltage at R=0 to 1, similar to the example of FIG. 7.

As shown in FIG. 10, when the area ratio R is larger than 0.8, the variation in the forward voltage rapidly increases. When the area ratio of the second cathode region 82 is large, the area of the first cathode region 81 required for conductivity modulation is proportionally small. Thus, it is considered that the impact of the line width variation of the first cathode region 81 becomes larger. The area ratio R is preferably 0.8 or less. The area ratio R may be 0.6 or less. This allows the variation in the forward voltage to be further suppressed. As shown in FIG. 10, when the area ratio R is less than 0.05, the variation in the forward voltage rapidly increases. It is considered that when the area ratio of the second cathode region 82 is too small, the impact of the line width variation of the first cathode region 81 strongly affects the extent of short circuit of the minority carriers in the second cathode region 82. The area ratio R is preferably 0.05 or more. The area ratio R may be 0.1 or more, or may be 0.15 or more. It is considered that by setting the area ratio of the second cathode region 82 to be in the range described above, a balance is stabilized between the effect of appropriately maintaining the concentration of minority carriers (holes in the present example) and the reduction effect of the carrier concentration due to short circuit of the minority carriers in the second cathode region 82, when the carrier lifetime is relatively long such as 1 us or more, and even if there is a line width variation in the first cathode region 81.

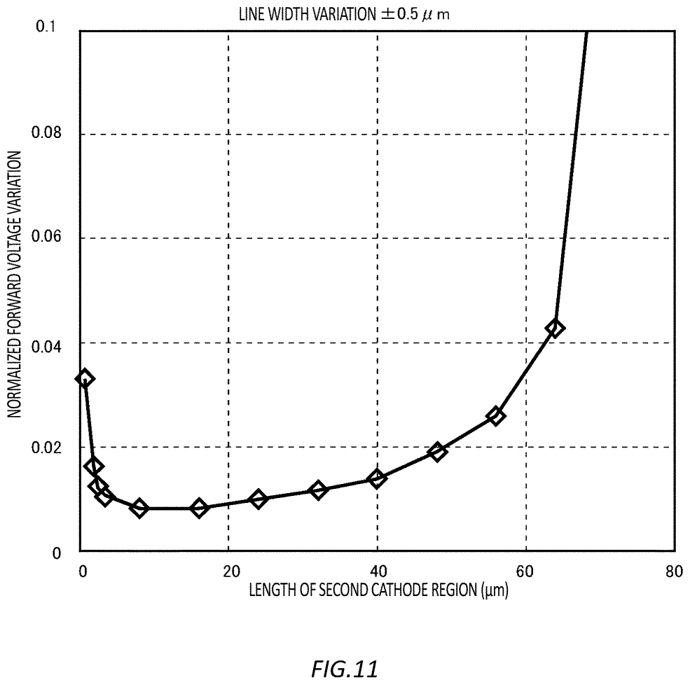

FIG. 11 shows a relationship between the magnitude of forward voltage variation due to patterning variation in the manufacturing process and the length Y2 in the second cathode region 82. The diode portion 80 of FIG. 11 has the structure shown in FIG. 5A, and its repetition pitch P is 80 μm. In the example of FIG. 11, the variation in patterning is assumed to be ±0.5 μm.

As shown in FIG. 11, when the length Y2 is larger than 65 μm, the variation in the forward voltage rapidly increases. When the length of the second cathode region 82 is long, the area of the first cathode region 81 required for conductivity modulation is proportionally small. Thus, it is considered that the impact of the line width variation of the first cathode region 81 becomes larger. The length Y2 is preferably 65 μm or less. The length Y2 may be 60 μm or less, or may be 55 μm or less. This allows the variation in the forward voltage to be further suppressed. As shown in FIG. 11, when the length Y2 is less than 4 μm, the variation in the forward voltage rapidly increases. It is considered that when the length of the second cathode region 82 is too short, the impact of the line width variation of the first cathode region 81 strongly affects the extent of short circuit of the minority carriers in the second cathode region 82. The length Y2 is preferably 4 μm or more. The length Y2 may be 8 μm or more, or may be 12 μm or more.

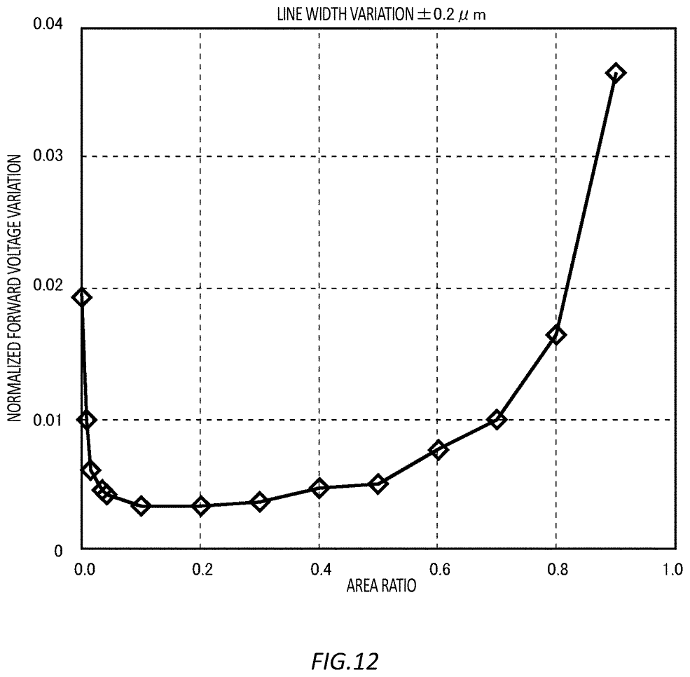

FIG. 12 shows a relationship between the magnitude of forward voltage variation and the area ratio R when the patterning variation is assumed to be ±0.2 μm. Again in the present example, a result similar to the example shown in FIG. 10 was obtained.

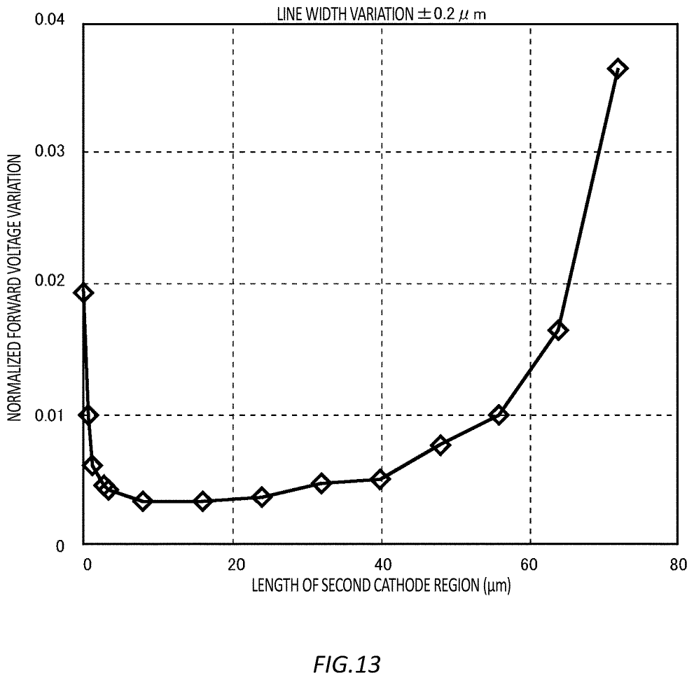

FIG. 13 shows a relationship between the magnitude of forward voltage variation and the length Y2 of the second cathode region 82 when the patterning variation is assumed to be ±0.2 μm. Again in the present example, a result similar to the example shown in FIG. 11 was obtained.

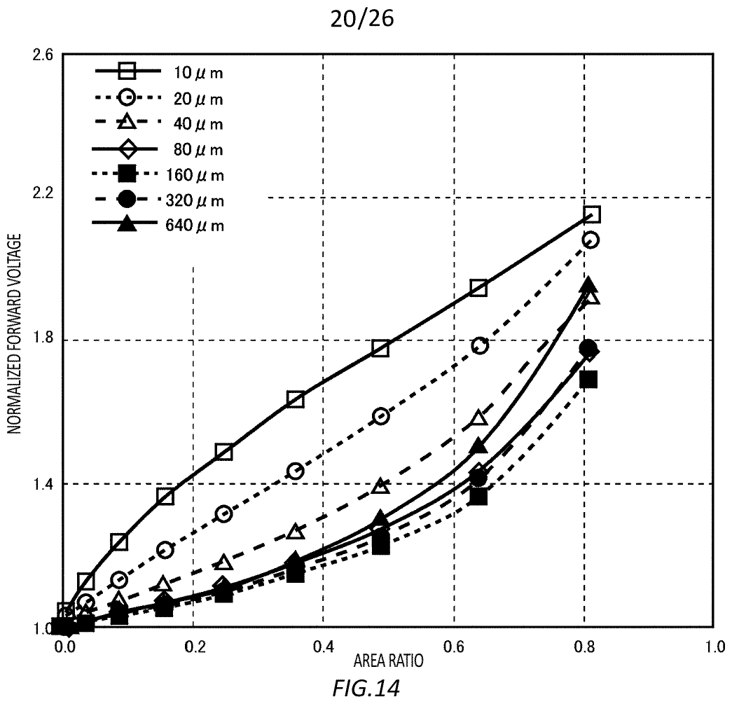

FIG. 14 shows another exemplary relationship between the area ratio R and the forward voltage in the diode portion 80. FIG. 14 shows a characteristic of each sample obtained by setting both the repetition pitch Px and Py in the example shown in FIG. 5A to 10 μm, 20 μm, 40 μm, 80 μm, 160 μm, 320 μm, or 640 μm. In each sample, Px=Py. Note that similar characteristics are also obtained in the example shown in FIG. 5B.

Similar to the example in FIG. 7, the area ratio R is preferably 0.8 or less. The area ratio R may be 0.7 or less, or may be 0.6 or less. Meanwhile, when the second cathode region 82 is too small, the effect of reducing the reverse recovery loss is decreased. The area ratio R is preferably 0.1 or more. The area ratio R may be 0.15 or more, or may be 0.2 or more.

In the example of FIG. 14, it is shown that when the repetition pitch P increases from 10 μm to 160 μm, the forward voltage tends to decrease. On the other hand, it is shown that when the repetition pitch P increases from 160 μm to 640 μm, the forward voltage tends to increase.

In the example of FIG. 14, since the four sides of the second cathode region 82 are surrounded by the first cathode region 81, the electrons injected from the first cathode region 81 during the on-operation of the diode portion 80 spread more easily above the entire second cathode region 82. Thus, compared to the example of FIG. 7, the region above the second cathode region 82 is more likely to operate as a diode over a wider range of repetition pitches P. Accordingly, it is considered that the example of FIG. 14 shows the tendency of the forward voltage decreasing even at a relatively large repetition pitch P.

As described above, while the repetition pitch P is increased from 10 μm to 160 μm, the forward voltage is decreased, whereas while the repetition pitch P is increased from 160 μm to 640 μm, the forward voltage is increased. Thus, the forward voltage is relatively stable when the repetition pitch P is in a range of 40 μm or more and 200 μm or less. The repetition pitch P is preferably 40 μm or more and 200 μm or less.

As shown in FIG. 14, when the repetition pitch P is 160 μm, the forward voltage is low compared to other samples. The repetition pitch P may be set to a value close to 160 μm. The repetition pitch P may be 80 μm or more, may be 100 μm or more, or may be 120 μm or more. The repetition pitch P may be 200 μm or less or may be 180 μm or less.

In other examples, the repetition pitch P may be 40 μm or more and 160 μm or less. In this region, as the repetition pitch P increases, the forward voltage increases. Thus, by adjusting the repetition pitch P, the forward voltage can be adjusted.

In the structure such as FIG. 5A in which the first cathode region 81 and the second cathode region 82 are alternately arranged also in the second direction (for example, in the X-axis direction) that is different from the first direction (for example, in the Y-axis direction), a larger area ratio R may be set compared to the structure such as FIG. 4A. The area ratio R may be 0.8 or less, may be 0.7 or less, or may be 0.6 or less.

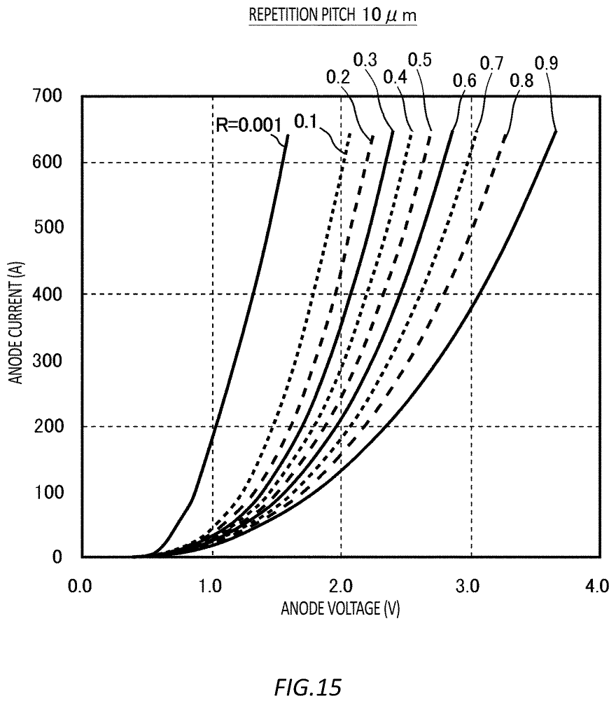

FIG. 15 shows a comparative example of an anode voltage-anode current characteristic in the diode portion 80. The diode portion 80 of FIG. 15 has the structure of FIG. 4A, and its repetition pitch P is 10 μm. The example of FIG. 15 shows the anode voltage-anode current characteristic when the area ratio R is varied from 0.001 to 0.9. With the small repetition pitch P, the variation in the anode voltage-anode current characteristic when the area ratio R is varied is large. In particular, the anode voltage-anode current characteristic when the area ratio R is 0.1 (that is, in a form in which the second cathode region 82 exists slightly) varies largely relative to the characteristic when the area ratio R is 0.001 (that is, in a form in which there is almost no second cathode region 82). Thus, with the repetition pitch P that is too small, it is difficult to precisely adjust the anode voltage-anode current characteristic in a region where a difference from the characteristic when the area ratio R is 0.001 is relatively small.

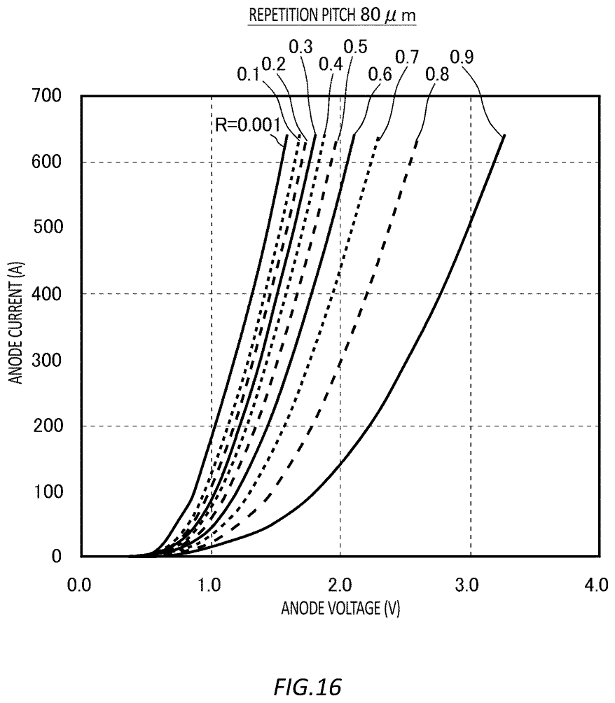

FIG. 16 shows another exemplary anode voltage-anode current characteristic in the diode portion 80. The diode portion 80 of FIG. 16 has the structure of FIG. 4A, and its repetition pitch P is 80 μm. As shown in FIG. 16, with the repetition pitch P that is relatively large, the variation in the anode voltage-anode current characteristic when the area ratio R is varied is small. In particular, compared to the example of FIG. 15, the anode voltage-anode current characteristic when the area ratio R is 0.1 (that is, in a form in which the second cathode region 82 exists slightly) varies less relative to the characteristic when the area ratio R is 0.001 (that is, in a form in which there is almost no second cathode region 82). Thus, the anode voltage-anode current characteristic can be precisely adjusted. From this aspect as well, the repetition pitch P may be 40 μm or more. The repetition pitch P may be 60 μm or more, or may be 80 μm or more.

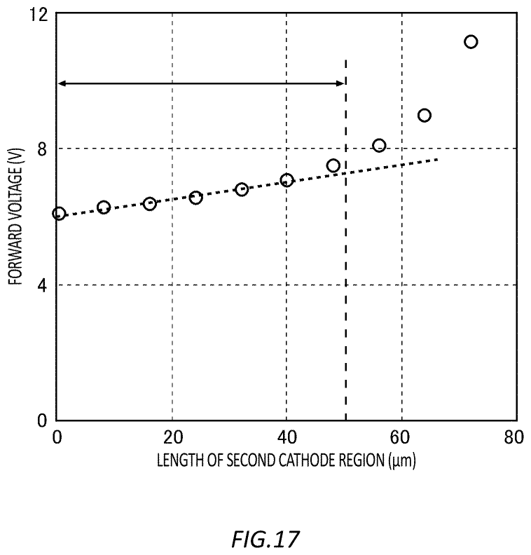

FIG. 17 shows a relationship between the length Y2 of the second cathode region 82 and the forward voltage. The diode portion 80 of the present example has the structure shown in FIG. 4A, and its repetition pitch P is 80 μm. As shown in FIG. 17, when the length Y2 is larger than 60 μm, the increase in forward voltage is sharp. The length Y2 may be 50 μm or less, where the forward voltage varies linearly. The area ratio R may be 0.6 or less.

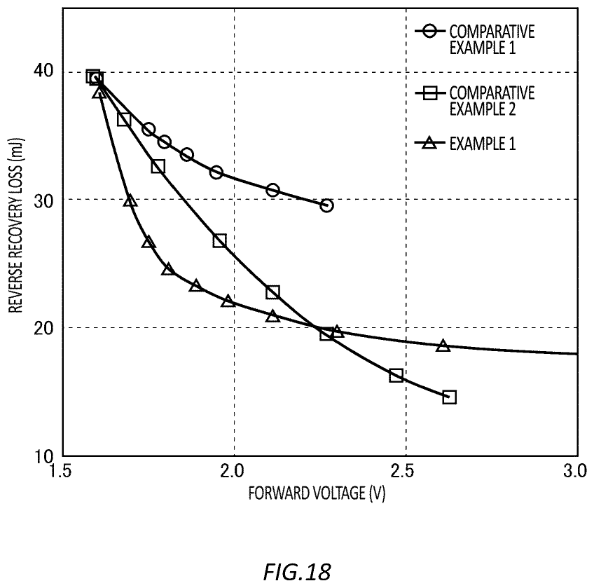

FIG. 18 shows the relationship of the forward voltage-reverse recovery loss of the diode portion 80. As shown in FIG. 18, the forward voltage and the reverse recovery loss in the diode portion 80 has a trade-off relationship. That is, the lower the reverse recovery loss is, the higher the forward voltage becomes. When the forward voltage becomes high, the loss during the ON-state of the diode portion 80 increases.

The comparative examples 1 and 2 are the example in which the cathode region 83 has the first cathode region 81 but does not include the second cathode region 82. The comparative example 1 shows the relationship of forward voltage-reverse recovery loss when the doping concentration of the anode region (base region 14) of the diode portion 80 is varied. The comparative example 2 shows the relationship of forward voltage-reverse recovery loss when the doping concentration of the cathode region 83 of the diode portion 80 is varied.

Example 1 shows the relationship of forward voltage-reverse recovery loss when the area ratio R is varied in the example in which the diode portion 80 has the structure of FIG. 4A and the repetition pitch is 80 μm. As shown in FIG. 18, the trade-off characteristic is improved in example 1 compared to the comparative examples 1 and 2.

In example 1, the doping concentrations of the base region 14 (anode region) of the diode portion 80 and the base region 14 of the transistor portion 70 are the same. Thus, the base region 14 of the diode portion 80 and the base region 14 of the transistor portion 70 can be created in the same ion implantation process. That is, the base regions 14 of the transistor portion 70 and the diode portion 80 can be formed by injecting dopant ions in parallel at the same dose amount using a common mask. In contrast, the manufacturing process of the comparative examples 1 and 2 is complicated because the doping concentration of the anode region of the diode portion 80 is varied.

In example 1, the doping concentration of the second cathode region 82 of the diode portion 80 is the same as the doping concentration of the collector region 22 of the transistor portion 70. Thus, the second cathode region 82 of the diode portion 80 and the collector region 22 of the transistor portion 70 can be created in the same ion implantation process. With such a structure, the semiconductor device 100 having an improved trade-off characteristic can be manufactured in a simple manufacturing process. Note that the base region 14 of the diode portion 80 and the base region 14 of the transistor portion 70 may have a different doping concentration. Also, the second cathode region 82 of the diode portion 80 and the collector region 22 of the transistor portion 70 may have a different doping concentration.

The dose amount of the dopant ion in the base region 14 (anode region) of the diode portion 80 may be 5.0×10¹²/cm² or more and 5.0×10¹³/cm² or less. As the dose amount of the dopant ion, a value obtained by integrating the doping concentration (/cm³) of the base region 14 in the depth direction may be used. When the base region 14 is in contact with the upper surface 21 and the drift region 18, the dose amount may be calculated by integrating the doping concentration of the base region 14 from the upper surface 21 to the drift region 18. In other examples, a value obtained by integrating the peak of the doping concentration of the base region 14 in the depth direction over a full width at half maximum range may be used as the dose amount.

The dose amount of the dopant ions in the second cathode region 82 may be 1.0×10¹³/cm² or more and 1.0×10¹⁴/cm² or less. As the dose amount of the dopant ion, a value obtained by integrating the doping concentration (/cm³) of the second cathode region 82 in the depth direction may be used. When the second cathode region 82 is in contact with the lower surface 23 and the N type region, the dose amount may be calculated by integrating the doping concentration of the second cathode region 82 from the lower surface 23 to the N type region. In other examples, a value obtained by integrating the peak of the doping concentration of the second cathode region 82 in the depth direction over a full width at half maximum range may be used as the dose amount.

In order to adjust the forward voltage and the reverse recovery loss, a carrier lifetime killer may be formed in the diode portion 80. For example, by forming charged particles of helium or the like below the anode region of the diode portion 80, a recombination center of the carriers can be formed in this place, and the carrier lifetime can be reduced.

In the semiconductor device 100 of the present example, there is no need to form the carrier lifetime killer in the diode portion 80. As described in FIGS. 1 to 18, the characteristic of the diode portion 80 can be adjusted by adjusting the repetition pitch P and the area ratio R of the cathode region 83. The carrier lifetime in the drift region 18 of the diode portion 80 may be 1 μs or more over the entire drift region 18. The carrier lifetime may be 2 μs or more, or may be 3 μs or more. The carrier lifetime may be 10 μs or more, may be 20 μs or more, or may be 30 μs or more. The carrier lifetime may be 10 ms or less, may be 1 ms or less, may be 500 μs or less, may be 200 μs or less, or 100 μs or less. Also, no helium may exist in the drift region 18 of the diode portion 80. The carrier lifetime in the drift region 18 of the diode portion 80 may exhibit a maximum value inside the semiconductor substrate 10. This configuration enables the omission of the process of forming the carrier lifetime killer, and the manufacturing process can be simplified. Also, it is possible to prevent the occurrence of leakage current due to carrier recombination centers or generation centers.

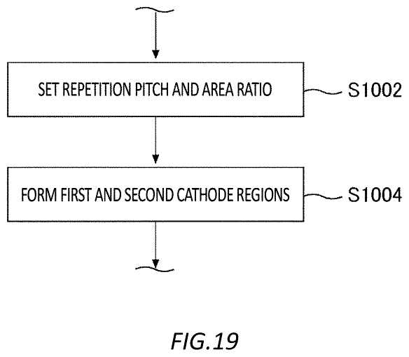

FIG. 19 illustrates the method for manufacturing the semiconductor device 100. In FIG. 19, the process to form the cathode region 83 in the manufacturing process of the semiconductor device 100 is shown. In the setting step S1002, the repetition pitch P and the area ratio R in the cathode region 83 are set. In the setting step S1002, the repetition pitch P and the area ratio R are set so that the forward voltage and the reverse recovery loss to be provided in the diode portion 80 fall within a predetermined range. In S1002, the repetition pitch P and the area ratio R may be set with reference to the characteristics as shown in FIG. 7 or FIG. 14. In the setting step S1002, the repetition pitch P is set to 40 μm or more and 200 μm or less, and the area ratio R is set to 0.1 or more and 0.8 or less. In the setting step S1002, the repetition pitch P and the area ratio Ras described in FIGS. 1 to 18 may be set.

In the forming step S1004, the first cathode region 81 and the second cathode region 82 are formed on the semiconductor substrate 10 so that the set repetition pitch P and the area ratio R are obtained. In the forming step S1004, the first cathode region 81 and the second cathode region 82 may be formed by injecting dopant ions from the lower surface 23 of the semiconductor substrate 10 and performing heat treatment.

In the forming step S1004, the collector region 22 of the transistor portion 70 may be formed in a process in common with the second cathode region 82. For example, in the forming step S1004, the dopant ions are injected using a mask that exposes a region on which the collector region 22 and the second cathode region 82 should be formed. Accordingly, the formation process of the second cathode region 82 and the collector region 22 can be simplified.

In the forming step S1004, the anode region (base region 14) of the diode portion 80 and the base region 14 of the transistor portion 70 may be formed in a common process. For example, in the forming step S1004, the dopant ions are injected using a mask that exposes a region on which the anode region and the base region 14 should be formed. Accordingly, the formation process of the anode region and the base region 14 can be simplified.

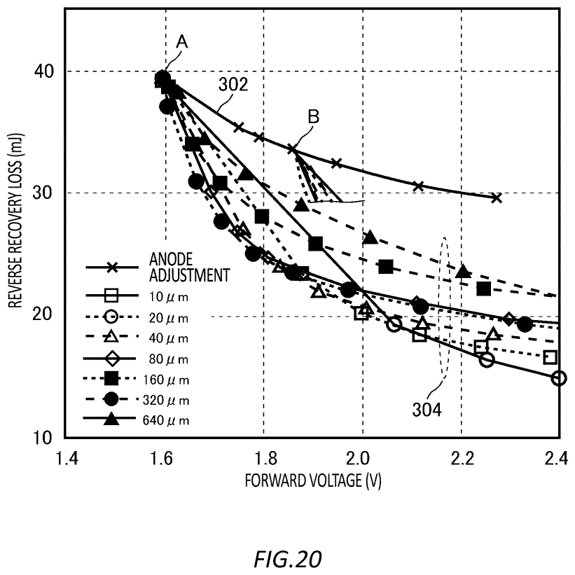

FIG. 20 illustrates an example of the designing step S1002. FIG. 20 shows the relationship of the forward voltage-reverse recovery loss of the diode portion 80. FIG. 20 shows the characteristic 302 of forward voltage-reverse recovery loss when the doping concentration of the anode region of the diode portion 80 is varied in the structure in which the cathode region 83 includes the first cathode region 81 but does not include the second cathode region 82. In addition, a group of characteristics 304 is also shown which are obtained from the diode portion 80 of the structure shown in FIG. 4A that has been formed with the doping concentration of the anode region at a predetermined reference point A in the characteristic 302. The group of characteristics 304 shows characteristics of respective samples in which the repetition pitch P is varied from 10 μm to 640 μm. In respective characteristics of the group of characteristics 304, the forward voltage and the reverse recovery loss are adjusted by varying the area ratio R.

In the designing step S1002, an initial value of the design value of the doping concentration of the anode region is set. The initial value is a doping concentration of the anode region at any point on the characteristic 302. In the example of FIG. 20, the doping concentration of the anode region at the reference point A is defined as the initial value.

In the designing step S1002, the characteristics of the forward voltage-reverse recovery loss of the diode portion 80 when this initial value is used is acquired for a plurality of repetition pitches P. In the example of FIG. 20, the group of characteristics 304 is acquired.

In the designing step S1002, based on the acquired group of characteristics 304, the design value of the doping concentration of the anode region may be adjusted. For example, among the respective characteristics included in the group of characteristics 304, the characteristic capable of achieving the desired forward voltage and the reverse recovery loss is selected, and the repetition pitch P and the area ratio R are determined based on this characteristic. Note that in some cases, the group of characteristics 304 relative to the reference point A may not include the desired forward voltage and reverse recovery loss. In this case, in the designing step S1002, a new reference point B is set and a new group of characteristics 304 relative to the reference point B is acquired so that the desired forward voltage and reverse recovery loss are obtained. For example, if it is desired to shift the range of the reverse recovery loss of the group of characteristics 304 in a direction in which the loss is reduced, the reference point B at which the forward voltage (and reverse recovery loss) is smaller than that at the reference point A is set. By increasing the doping concentration of the anode region, the forward voltage can be reduced. Such a process may be performed repeatedly until the desired forward voltage and the reverse recovery loss can be set.

In the present specification, the descriptions shown in the following items are included.

### (Item 1)

A semiconductor device comprising a semiconductor substrate which has an upper surface and a lower surface, and which is provided with a diode portion, wherein
the diode portion includes
a drift region of a first conductivity type provided on the semiconductor substrate, and
a cathode region of a first conductivity type or a second conductivity type which is provided in contact with the lower surface of the semiconductor substrate and which has a doping concentration higher than that of the drift region, wherein
the cathode region includes
a first cathode region of a first conductivity type, and
a second cathode region of a second conductivity type provided in contact with the lower surface of the semiconductor substrate, and wherein
the first cathode region and the second cathode region are provided alternately in a first direction, and a repetition pitch of the first cathode region and the second cathode region in the first direction is 200 μm or less, and
an area ratio of the second cathode region relative to a sum of areas of the first cathode region and the second cathode region is 0.1 or more and 0.8 or less.

### (Item 2)

The semiconductor device according to item 1, wherein
the repetition pitch is 80 μm or more and 160 μm or less.

### (Item 3)

The semiconductor device according to item 2, wherein
the area ratio is 0.6 or less.

### (Item 4)

The semiconductor device according to item 1, wherein
each of the first cathode region and the second cathode region has a longitudinal length in a longitudinal direction which is different from the first direction, and
the area ratio is 0.5 or less.

### (Item 5)

The semiconductor device according to item 1, wherein
the first cathode region and the second cathode region are arranged alternately also in a second direction which is different from the first direction, and
the area ratio is 0.6 or less.

### (Item 6)

The semiconductor device according to item 1, wherein
the repetition pitch is 100 μm or more and 130 μm or less.

### (Item 7)

The semiconductor device according to item 1, wherein
the repetition pitch is 80 μm or less.

### (Item 8)

The semiconductor device according to any one of items 1 to 7, wherein
the diode portion includes an anode region of a second conductivity type provided in contact with the upper surface of the semiconductor substrate, and
a dose amount of dopant ions of the anode region is 5.0×10¹²/cm² or more and 5.0×10¹³/cm² or less.

### (Item 9)

The semiconductor device according to item 8, wherein
a dose amount of dopant ions of the second cathode region is 1.0×10¹³/cm² or more and 1.0×10¹⁴/cm² or less.

### (Item 10)

The semiconductor device according to any one of items 1 to 7, wherein
a transistor portion connected in anti-parallel with the diode portion is provided in the semiconductor substrate.

### (Item 11)

The semiconductor device according to item 10, wherein
the transistor portion includes a collector region of a second conductivity type provided in contact with the lower surface of the semiconductor substrate, and
a doping concentration of the second cathode region and a doping concentration of the collector region are the same.

### (Item 12)

The semiconductor device according to item 10, wherein
the diode portion includes an anode region of a second conductivity type provided in contact with the upper surface of the semiconductor substrate,
the transistor portion includes
an emitter region of a first conductivity type provided in contact with the upper surface of the semiconductor substrate,
the drift region, and
a base region of a second conductivity type provided between the emitter region and the drift region, and
a doping concentration of the anode region and a doping concentration of the base region are the same.

### (Item 13)

The semiconductor device according to any one of items 1 to 7, wherein
a carrier lifetime in the drift region of the diode portion is 1 μs or more.

### (Item 14)

The semiconductor device according to item 1, wherein
the first cathode region and the second cathode region are arranged alternately also in a second direction which is different from the first direction, and
at least one first cathode region, identical to the first cathode region, is surrounded by the second cathode region.

### (Item 15)

The semiconductor device according to item 10, comprising:
a boundary between the transistor portion and the diode portion, wherein
a distance between a part of the boundary extending in the first direction and an end portion of the first cathode region facing the part of the boundary extending in the first direction is less than a length of the first cathode region in a second direction which is different from the first direction.

### (Item 16)

The semiconductor device according to item 5, wherein
in a top view of the semiconductor substrate, an end portion of a contact hole of the diode portion is positioned outside a part of the boundary extending in the second direction, and
in a top view of the semiconductor substrate, a length of the contact hole protruding from the part of the boundary extending in the second direction is less than a length of a repetition structure of the first cathode region and the second cathode region in the first direction.

### (Item 17)

The semiconductor device according to item 1, wherein
at least one second cathode region, identical to the second cathode region, is surrounded by the first cathode region, and
the diode portion includes a margin region of a second conductivity type which is provided in contact with the lower surface of the semiconductor substrate and which surrounds the first cathode region.

### (Item 18)

The semiconductor device according to item 1, wherein
a chamfered portion is provided on a corner at an outermost position of one or more first cathode regions, each being identical to the first cathode region.

### (Item 19)

The semiconductor device according to item 1, wherein
the first cathode region and the second cathode region are arranged alternately also in a second direction which is different from the first direction, and
an end portion of the first cathode region in the first direction is arranged inward relative to an end portion of the second cathode region in the first direction.

### (Item 20)

The semiconductor device according to item 19, wherein
an end portion of the first cathode region in the second direction is arranged inward relative to an end portion of the second cathode region in the second direction.

### (Item 21)

The semiconductor device according to item 1 or 7, wherein
the repetition pitch is 40 μm or more.

### (Item 22)

The semiconductor device according to item 4, wherein
the area ratio is 0.4 or less.

### (Item 23)

A method for manufacturing a semiconductor device having a semiconductor substrate which has an upper surface and a lower surface, which has a drift region of a first conductivity type, and which is provided with a diode portion, the method comprising:
forming a first cathode region of a first conductivity type which is provided in contact with the lower surface of the semiconductor substrate and which has a doping concentration higher than that of the drift region, and a second cathode region of a second conductivity type provided in contact with the lower surface of the semiconductor substrate, wherein
the forming the first cathode region and the second cathode region includes
   providing the first cathode region and the second cathode region alternately in a first direction, and setting a repetition pitch of the first cathode region and the second cathode region in the first direction to 200 μm or less, and
   setting an area ratio of the second cathode region relative to a sum of areas of the first cathode region and the second cathode region to 0.1 or more and 0.8 or less.

### (Item 24)

The method for manufacturing the semiconductor device according to item 23, wherein
the semiconductor device includes a transistor portion which is provided on the semiconductor substrate and which is connected in anti-parallel with the diode portion, and
the transistor portion includes a collector region of a second conductivity type provided in contact with the lower surface of the semiconductor substrate, the method comprising: forming the collector region in a process in common with the second cathode region.

### (Item 25)

The method for manufacturing the semiconductor device according to item 23, wherein
the semiconductor device includes a transistor portion which is provided on the semiconductor substrate and which is connected in anti-parallel with the diode portion,
the diode portion includes an anode region of a second conductivity type provided in contact with the upper surface of the semiconductor substrate, and
the transistor portion includes
an emitter region of a first conductivity type provided in contact with the upper surface of the semiconductor substrate,
the drift region, and
a base region of a second conductivity type provided between the emitter region and the drift region, the method comprising:
forming the anode region and the base region in a common process.

### (Item 26)

The method for manufacturing the semiconductor device according to item 23, wherein
the diode portion includes an anode region of a second conductivity type provided in contact with the upper surface of the semiconductor substrate, the method comprising:
setting an initial value of a design value of a doping concentration of the anode region;
acquiring, for a plurality of repetition pitches, each being identical to the repetition pitch, a plurality of characteristics of forward voltage-reverse recovery loss of the diode portion when the initial value is used; and
adjusting the design value of the doping concentration of the anode region based on the plurality of characteristics of forward voltage-reverse recovery loss for the plurality of repetition pitches.

### (Item 27)

The method for manufacturing the semiconductor device according to item 23, comprising:
setting the repetition pitch to 80 μm or less.

### (Item 28)

The method for manufacturing the semiconductor device according to item 27, comprising:
setting the repetition pitch to 40 μm or more.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can fall within the technical scope of the present invention.

Each process of the operations, procedures, steps, stages, and the like performed by a device, system, program, and method shown in the claims, the specification, and the drawings can be performed in any order as long as the order is not indicated by “prior to,” “before,” and the like and as long as the output from a previous process is not used in a later process. Even if the operational flow is described using phrases such as “first” or “next” for convenience in the claims, the specification, and the drawings, it does not necessarily mean that the process must be performed in this order.

What is claimed is:

1. A semiconductor device comprising a semiconductor substrate which has an upper surface and a lower surface, and which is provided with a diode portion, wherein
the diode portion includes
a drift region of a first conductivity type provided on the semiconductor substrate, and
a cathode region of a first conductivity type or a second conductivity type which is provided in contact with the lower surface of the semiconductor substrate and which has a doping concentration higher than that of the drift region, wherein
the cathode region includes
a first cathode region of a first conductivity type, and
a second cathode region of a second conductivity type provided in contact with the lower surface of the semiconductor substrate, and wherein
the first cathode region and the second cathode region are provided alternately in a first direction, and a repetition pitch of the first cathode region and the second cathode region in the first direction is 200 μm or less, and
an area ratio of the second cathode region relative to a sum of areas of the first cathode region and the second cathode region is 0.1 or more and 0.8 or less.

2. The semiconductor device according to claim 1, wherein
the repetition pitch is 80 μm or more and 160 μm or less.

3. The semiconductor device according to claim 2, wherein
the area ratio is 0.6 or less.

4. The semiconductor device according to claim 1, wherein
each of the first cathode region and the second cathode region has a longitudinal length in a longitudinal direction which is different from the first direction, and
the area ratio is 0.5 or less.

5. The semiconductor device according to claim 1, wherein
the first cathode region and the second cathode region are arranged alternately also in a second direction which is different from the first direction, and
the area ratio is 0.6 or less.

6. The semiconductor device according to claim 1, wherein
the repetition pitch is 80 μm or less.

7. The semiconductor device according to claim 1, wherein
the diode portion includes an anode region of a second conductivity type provided in contact with the upper surface of the semiconductor substrate, and
a dose amount of dopant ions of the anode region is 5.0×10¹²/cm² or more and 5.0×10¹³/cm² or less.

8. The semiconductor device according to claim 7, wherein
a dose amount of dopant ions of the second cathode region is 1.0×10¹³/cm² or more and 1.0×10¹⁴/cm² or less.

9. The semiconductor device according to claim 1, wherein
a transistor portion connected in anti-parallel with the diode portion is provided in the semiconductor substrate.

10. The semiconductor device according to claim 1, wherein
a carrier lifetime in the drift region of the diode portion is 1 μs or more.

11. The semiconductor device according to claim 1, wherein
the first cathode region and the second cathode region are arranged alternately also in a second direction which is different from the first direction, and
at least one first cathode region, identical to the first cathode region, is surrounded by the second cathode region.

12. The semiconductor device according to claim 9, comprising:
a boundary between the transistor portion and the diode portion, wherein
a distance between a part of the boundary extending in the first direction and an end portion of the first cathode region facing the part of the boundary extending in the first direction is less than a length of the first cathode region in a second direction which is different from the first direction.

13. The semiconductor device according to claim 5, wherein
in a top view of the semiconductor substrate, an end portion of a contact hole of the diode portion is positioned outside a part of a boundary extending in the second direction, and
in a top view of the semiconductor substrate, a length of the contact hole protruding from the part of the boundary extending in the second direction is less than a length of a repetition structure of the first cathode region and the second cathode region in the first direction.

14. The semiconductor device according to claim 1, wherein
at least one second cathode region, identical to the second cathode region, is surrounded by the first cathode region, and
the diode portion includes a margin region of a second conductivity type which is provided in contact with the lower surface of the semiconductor substrate and which surrounds the first cathode region.

15. The semiconductor device according to claim 1, wherein
a chamfered portion is provided on a corner at an outermost position of one or more first cathode regions, each being identical to the first cathode region.

16. The semiconductor device according to claim 1, wherein
the first cathode region and the second cathode region are arranged alternately also in a second direction which is different from the first direction, and
an end portion of the first cathode region in the first direction is arranged inward relative to an end portion of the second cathode region in the first direction.

17. The semiconductor device according to claim 16, wherein
an end portion of the first cathode region in the second direction is arranged inward relative to an end portion of the second cathode region in the second direction.

18. The semiconductor device according to claim 1, wherein
the repetition pitch is 40 μm or more.

19. The semiconductor device according to claim 4, wherein
the area ratio is 0.4 or less.

20. A method for manufacturing a semiconductor device having a semiconductor substrate which has an upper surface and a lower surface, which has a drift region of a first conductivity type, and which is provided with a diode portion, the method comprising:
forming a first cathode region of a first conductivity type which is provided in contact with the lower surface of the semiconductor substrate and which has a doping concentration higher than that of the drift region, and a second cathode region of a second conductivity type provided in contact with the lower surface of the semiconductor substrate, wherein
the forming the first cathode region and the second cathode region includes
providing the first cathode region and the second cathode region alternately in a first direction, and setting a repetition pitch of the first cathode region and the second cathode region in the first direction to 200 μm or less, and
setting an area ratio of the second cathode region relative to a sum of areas of the first cathode region and the second cathode region to 0.1 or more and 0.8 or less.

21. The method for manufacturing the semiconductor device according to claim 20, wherein
the semiconductor device includes a transistor portion which is provided on the semiconductor substrate and which is connected in anti-parallel with the diode portion, and
the transistor portion includes a collector region of a second conductivity type provided in contact with the lower surface of the semiconductor substrate, the method comprising:
forming the collector region in a process in common with the second cathode region.

22. The method for manufacturing the semiconductor device according to claim 20, wherein
the diode portion includes an anode region of a second conductivity type provided in contact with the upper surface of the semiconductor substrate, the method comprising:
setting an initial value of a design value of a doping concentration of the anode region;
acquiring, for a plurality of repetition pitches, each being identical to the repetition pitch, a plurality of characteristics of forward voltage-reverse recovery loss of the diode portion when the initial value is used; and
adjusting the design value of the doping concentration of the anode region based on the plurality of characteristics of forward voltage-reverse recovery loss for the plurality of repetition pitches.

23. The method for manufacturing the semiconductor device according to claim 20, comprising:
setting the repetition pitch to 80 μm or less.

24. The method for manufacturing the semiconductor device according to claim 23, comprising:
setting the repetition pitch to 40 μm or more.
